(19) United States
(12) Patent Application Publication
(10) Pub. No.: US 2026/0271552 A1
(43) Pub. Date: Sep. 10, 2026

(54) DISPLAY APPARATUS, ELECTRONIC APPARATUS INCLUDING THE DISPLAY APPARATUS, AND METHOD OF MANUFACTURING THE DISPLAY APPARATUS

(71) Applicant: Samsung Display Co., Ltd., Yongin-si (KR)

(72) Inventors: Doyeong Park, Yongin-si (KR); Donghee Shin, Yongin-si (KR)

(21) Appl. No.: 19/558,093

(22) Filed: Mar. 5, 2026

(30) Foreign Application Priority Data
Mar. 10, 2025 (KR) 10-2025-0030596

(51) Int. Cl. H10K 59/126; H10K 59/12

(52) U.S. Cl. CPC H10K 59/126; H10K 59/1201

(57) ABSTRACT

A display apparatus includes: a substrate; a pixel layer over the substrate and comprising a pixel circuit and a display element; and a shading unit over the pixel layer, wherein the shading unit includes: a plurality of first shading walls extending in a first direction and spaced apart from each other in a second direction intersecting the first direction; a plurality of second shading walls extending in the second direction and spaced apart from each other in the first direction; and a plurality of third shading walls protruding from the plurality of first shading walls in the first direction and spaced apart from each other in the first direction and the second direction.

### CROSS-REFERENCE TO RELATED APPLICATION

The present application claims priority to and the benefit of Korean Patent Application No. 10-2025-0030596, filed on Mar. 10, 2025, in the Korean Intellectual Property Office, the entire disclosure of which is incorporated herein by reference.

### BACKGROUND

### 1. Field

Aspects of some embodiments relate to apparatuses and methods, and for example, to a display apparatus, an electronic apparatus including the display apparatus, and a method of manufacturing the display apparatus.

### 2. Description of the Related Art

Recently, display apparatuses have been used for various purposes. Also, display apparatuses have become relatively thinner and lighter and thus their range of uses has expanded. Thus, display apparatuses may be used in various fields and accordingly consumer demand for display apparatuses capable of displaying high-quality images has increased. Display apparatuses may also be arranged in vehicles to display images to users sitting in a driver's seat or a passenger seat.

The above information disclosed in this Background section is only for enhancement of understanding of the background and therefore the information discussed in this Background section does not necessarily constitute prior art.

### SUMMARY

Light emitted from a display apparatus arranged in a vehicle may be reflected by a vehicle window and then may reach a driver. In this case, the driver's view may be obstructed during driving, and thus, a safety problem may occur during driving.

In order to solve various problems including the above problems, one or more embodiments include a display apparatus configured to restrict a viewing angle of light emitted from the display apparatus and a method of manufacturing the display apparatus. However, these characteristics are merely examples and the scope of embodiments according to the present disclosure are not limited thereto.

Additional aspects will be set forth in part in the description which follows and, in part, will be apparent from the description, or may be learned by practice of the presented embodiments of the disclosure.

According to one or more embodiments, a display apparatus includes a substrate, a pixel layer arranged over the substrate and including a pixel circuit and a display element, and a shading unit arranged over the pixel layer, wherein the shading unit includes a plurality of first shading walls extending in a first direction and spaced apart from each other in a second direction intersecting the first direction, a plurality of second shading walls extending in the second direction and spaced apart from each other in the first direction, and a plurality of third shading walls protruding from the plurality of first shading walls in the first direction and spaced apart from each other in the first direction and the second direction.

According to some embodiments, a distance between two third shading walls arranged adjacent to each other in the second direction may be greater than a distance between two first shading walls arranged adjacent to each other in the second direction.

According to some embodiments, a distance between two first shading walls arranged adjacent to each other in the second direction may be equal to a length of each of the plurality of third shading walls in the second direction.

According to some embodiments, the shading unit may further include a plurality of first shading openings arranged between the plurality of first shading walls and the plurality of third shading walls, and a plurality of second shading openings arranged between the plurality of first shading walls and the plurality of second shading walls.

According to some embodiments, a length of each of the plurality of second shading openings in the first direction may be greater than a length of each of the plurality of first shading openings in the first direction.

According to some embodiments, the shading unit may further include a transparent layer accommodated in the plurality of first shading openings and the plurality of second shading openings.

According to some embodiments, a thickness of each of the plurality of second shading walls may be greater than a thickness of each of the plurality of first shading walls.

According to some embodiments, the plurality of first shading walls and the plurality of second shading walls may intersect each other at a plurality of intersection portions.

According to one or more embodiments, an electronic apparatus including a display apparatus, wherein the display apparatus includes a substrate, a pixel layer arranged over the substrate and including a pixel circuit and a display element, and a shading unit arranged over the pixel layer, wherein the shading unit includes a plurality of first shading walls extending in a first direction and spaced apart from each other in a second direction intersecting the first direction, a plurality of second shading walls extending in the second direction and spaced apart from each other in the first direction, and a plurality of third shading walls protruding from the plurality of first shading walls in the first direction and spaced apart from each other in the first direction and the second direction.

According to some embodiments, a distance between two third shading walls arranged adjacent to each other in the second direction may be greater than a distance between two first shading walls arranged adjacent to each other in the second direction, and a distance between two second shading walls arranged adjacent to each other in the second direction may be equal to a length of each of the plurality of third shading walls in the second direction.

According to one or more embodiments, a method of manufacturing a display apparatus includes arranging a pixel layer over a substrate including a plurality of first areas, a plurality of second areas, and a plurality of third areas arranged between the plurality of first areas and the plurality of second areas, arranging a shading layer over the pixel layer to overlap the plurality of first areas, the plurality of second areas, and the plurality of third areas, arranging a first layer over the shading layer to overlap the plurality of first areas, the plurality of second areas, and the plurality of third areas, arranging a first organic layer including a first organic opening over the first layer to overlap the plurality of first areas and the plurality of third areas, arranging a first inorganic layer over the first layer to overlap the plurality of first areas, the plurality of second areas, and the plurality of third areas, arranging a second organic layer over the first inorganic layer to overlap the plurality of second areas and the plurality of third areas, etching the first inorganic layer such that a first inorganic opening is formed in the first inorganic layer arranged in the plurality of first areas and the plurality of third areas, removing the first organic layer and the second organic layer, etching the first layer such that a first layer opening overlapping the first inorganic opening is formed in the first layer, etching the shading layer such that a plurality of shading openings overlapping the first layer opening is formed in the shading layer, and removing the first inorganic layer and the first layer.

According to some embodiments, in the arranging of the first inorganic layer, the first inorganic layer arranged in the plurality of first areas and the plurality of third areas may cover the first organic layer.

According to some embodiments, in the arranging of the second organic layer, a height of the second organic layer in the plurality of third areas may be less than or equal to a height of the first organic layer.

According to some embodiments, the method may further include arranging a transparent layer in the plurality of shading openings.

According to some embodiments, the plurality of shading openings may include a plurality of first shading openings arranged in the plurality of first areas, and a plurality of second shading openings arranged in each of the plurality of first areas and the plurality of third areas.

According to some embodiments, a length of each of the plurality of second shading openings in a first direction may be greater than a length of each of the plurality of first shading openings in the first direction.

According to some embodiments, a shading wall may be formed in the etching of the shading layer, and the shading wall may include a plurality of first shading walls extending in a first direction and spaced apart from each other in a second direction intersecting the first direction, a plurality of second shading walls extending in the second direction and spaced apart from each other in the first direction, and a plurality of third shading walls protruding from the plurality of first shading walls in the first direction and spaced apart from each other in the first direction and the second direction.

According to some embodiments, a distance between two third shading walls arranged adjacent to each other in the second direction may be greater than a distance between two first shading walls arranged adjacent to each other in the second direction.

According to some embodiments, a distance between two second shading walls arranged adjacent to each other in the second direction may be equal to a length of each of the plurality of third shading walls in the second direction.

According to some embodiments, a thickness of each of the plurality of second shading walls may be greater than a thickness of each of the plurality of first shading walls.

Other aspects, features, and characteristics other than those described above will be apparent from the accompanying drawings, the attached claims, and the detailed description of the disclosure.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a display apparatus according to some embodiments;

FIG. 2 is a cross-sectional view schematically illustrating a display apparatus according to some embodiments;

FIG. 3 is an equivalent circuit diagram of a pixel according to some embodiments;

FIG. 4 is a plan view schematically illustrating a display apparatus according to some embodiments;

FIGS. 5 and 6 are plan views schematically illustrating a display apparatus according to some embodiments;

FIGS. 7A to 7C are cross-sectional views schematically illustrating a display apparatus according to some embodiments;

FIG. 8 is a flowchart schematically illustrating a method of manufacturing a display apparatus according to some embodiments;

FIGS. 9A to 16C are cross-sectional views schematically illustrating a display apparatus according to some embodiments;

FIG. 17 is a block diagram of an electronic apparatus according to some embodiments; and

FIG. 18 shows schematic diagrams of electronic apparatuses according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, embodiments according to the present disclosure are not limited to the embodiments described below and may be implemented in various forms.

Hereinafter, aspects of some embodiments will be described in more detail with reference to the accompanying drawings, and in the following description, like reference numerals will denote like elements and redundant descriptions thereof will be omitted for conciseness.

It will be understood that although terms such as "first" and "second" may be used herein to describe various elements, these elements should not be limited by these terms and these terms are only used to distinguish one element from another element.

As used herein, the singular forms "a," "an," and "the" are intended to include the plural forms as well, unless the context clearly indicates otherwise.

It will be understood that terms such as "comprise," "include," and "have" used herein specify the presence of stated features or elements, but do not preclude the presence or addition of one or more other features or elements.

It will be understood that when a layer, region, or element is referred to as being "on" another layer, region, or element, it may be "directly on" the other layer, region, or element or may be "indirectly on" the other layer, region, or element with one or more intervening layers, regions, or elements therebetween.

Sizes of elements in the drawings may be exaggerated for convenience of description. In other words, because the sizes and shapes of elements in the drawings are arbitrarily illustrated for convenience of description, embodiments according to the present disclosure are not limited thereto.

Also, herein, the X axis, the Y axis, and the Z axis are not limited to three axes of the rectangular coordinate system and may be interpreted in a broader sense. For example, the X axis, the Y axis, and the X axis may be perpendicular to one another or may represent different directions that are not perpendicular to one another.

When a certain embodiment may be implemented differently, a particular process order may be performed differently from the described order. For example, two consecutively described processes may be performed at the same time (or substantially at the same time) or performed in an order opposite to the described order.

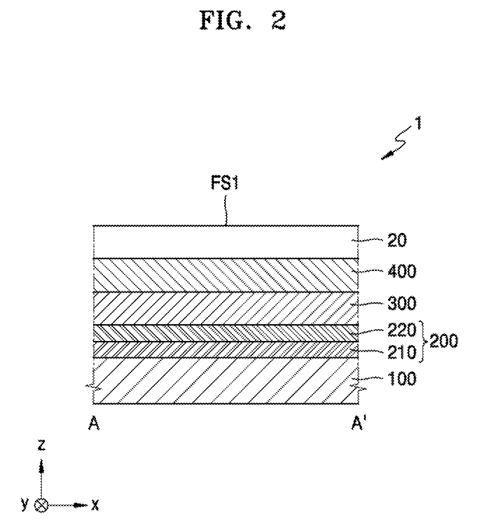

Herein, "in a plan view" may mean a view in a direction perpendicular to a substrate 100 (see FIG. 2). For example, "A and B spaced apart from each other in a plan view" may mean "A and B spaced apart from each other when viewed in a direction perpendicular to the substrate 100 (see FIG. 2)."

Herein, "in a cross-sectional view" may mean the case of being taken in a direction perpendicular to the substrate 100 (see FIG. 2). For example, "A and B spaced apart from each other in a cross-sectional view" may mean "A and B spaced apart from each other in a direction perpendicular to the substrate 100 (see FIG. 2)."

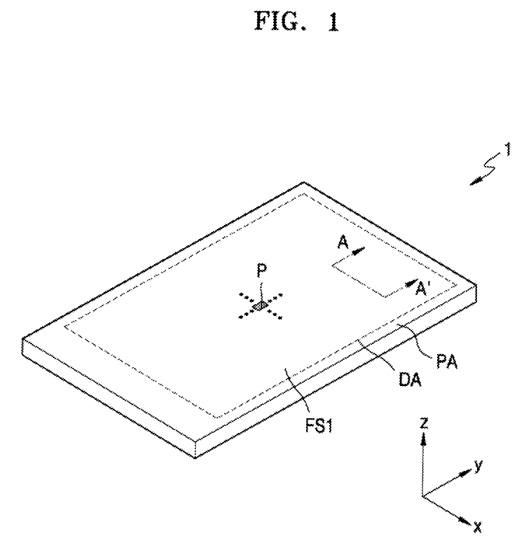

FIG. 1 is a perspective view schematically illustrating a display apparatus 1 according to some embodiments, and FIG. 2 is a cross-sectional view schematically illustrating the display apparatus 1 according to some embodiments.

Particularly, FIG. 2 is a cross-sectional view of the display apparatus 1 taken along the line A-A' of FIG. 1.

Referring to FIG. 1, the display apparatus 1 according to some embodiments may include a display area DA and a peripheral area PA. The peripheral area PA may be arranged outside (e.g., in a periphery or outside a footprint of) the display area DA to surround the display area DA. A driving circuit unit and various lines for transmitting electrical signals to be applied to the display area DA may be located in the peripheral area PA. The display apparatus 1 may display images by using light emitted from a plurality of pixels P arranged in the display area DA.

Hereinafter, as an example, the display apparatus 1 will be described as an organic light emitting display apparatus. However, embodiments according to the present disclosure are not limited thereto. The display apparatus 1 may be a display apparatus such as an organic light emitting display apparatus, an inorganic light emitting display apparatus (or an inorganic EL display apparatus), or a quantum dot light emitting display apparatus.

As illustrated in FIG. 2, the display apparatus 1 may include a substrate 100, a pixel layer 200, an encapsulation layer 300, a shading unit 400, and a cover window 20 sequentially stacked in a third direction (e.g., z-axis direction).

The substrate 100 may include a glass material or may include a polymer resin. For example, the substrate 100 may include a glass material including silicon oxide (SiOₓ) as a main component or may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The pixel layer 200 may be arranged over the substrate 100. The pixel layer 200 may include a pixel circuit layer 210 including a pixel circuit and insulating layers, and a display element layer 220 including display elements. The display element layer 220 may be arranged over the pixel circuit layer 210, and a plurality of insulating layers may be arranged between the pixel circuit and the display element. Some lines and insulating layers of the pixel circuit layer 210 may extend to the peripheral area PA.

The encapsulation layer 300 may be arranged over the pixel layer 200. The encapsulation layer 300 may encapsulate the display elements located in the display element layer 220. According to some embodiments, the encapsulation layer 300 may include at least one inorganic encapsulation layer and at least one organic encapsulation layer. The at least one inorganic encapsulation layer may include one or more inorganic materials among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). The at least one organic encapsulation layer may include a polymer-based material. The polymer-based material may include acryl-based resin, epoxy-based resin, polyimide, polyethylene, or the like. According to some embodiments, the at least one organic encapsulation layer may include acrylate.

The shading unit 400 may be arranged over the encapsulation layer 300. The shading unit 400 may at least partially absorb external light or internally reflected light to restrict a viewing angle of light emitted from the display element layer 220. For example, the shading unit 400 may transmit light emitted perpendicularly to a front surface FS1 (see, e.g., FIG. 1) of the display apparatus 1 and may block light emitted at a certain range of angles to the front surface FSb of the display apparatus 1. For example, the shading unit 400 may block light emitted at an angle of 45° (or about 45°) or less to the front surface FS1 of the display apparatus 1. The shading unit 400 may be arranged in the display area DA. The shading unit 400 may include a transmission area such that light emitted from the display element arranged in the display area DA passes to the outside.

According to some embodiments, a touch sensor layer may be further included between the encapsulation layer 300 and the shading unit 400. As a layer for sensing a user's touch input, the touch sensor layer may detect a user's touch input by using at least one of various touch methods such as a resistive method and a capacitive method.

The cover window 20 may be arranged over the shading unit 400. According to some embodiments, through an adhesive such as an optically clear adhesive (OCA), the cover window 20 may be coupled to a component thereunder, for example, the shading unit 400. The cover window 20 may protect the substrate 100, the pixel layer 200, the encapsulation layer 300, and the shading unit 400. The cover window 20 may include at least one of glass, sapphire, or plastic. The cover window 20 may include, for example, ultra-thin glass (UTG) or colorless polyimide (CPI).

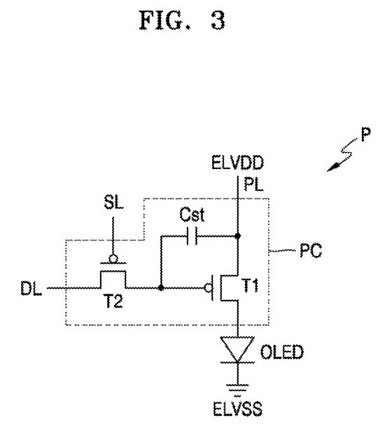

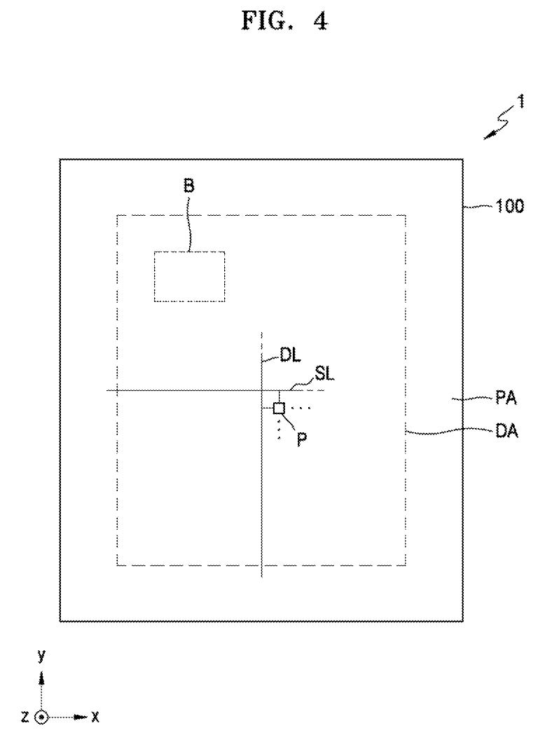

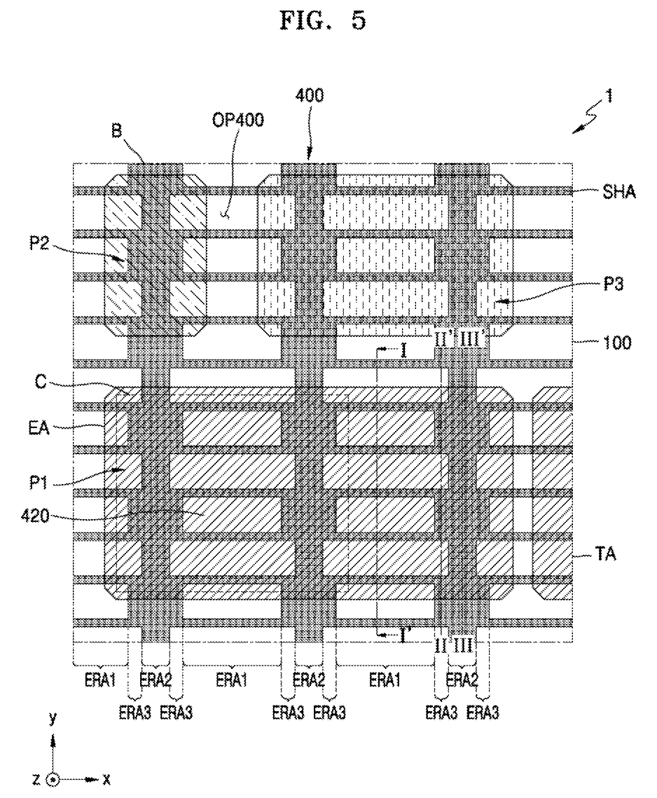

FIG. 3 is an equivalent circuit diagram of a pixel P according to some embodiments. Although FIG. 3 illustrates various components in a pixel according to some embodiments, embodiments according to the present disclosure are not limited thereto, and according to various embodiments, the pixel may include additional components without departing from the spirit and scope of the embodiments according to the present disclosure. FIG. 4 is a plan view schematically illustrating the display apparatus 1 according to some embodiments.

Referring to FIGS. 3 and 4, the substrate 100 of the display apparatus 1 may be divided into a display area DA and a peripheral area PA. The display apparatus 1 may display images by using light emitted from a plurality of pixels P arranged in the display area DA.

Each pixel P may include a display element such as an organic light emitting diode OLED or an inorganic light emitting diode and may emit, for example, red, green, blue, or white light. That is, each pixel P may be connected to a pixel circuit PC including a thin film transistor (TFT) and a storage capacitor Cst. The pixel circuit PC may be connected to a scan line SL, a data line DL intersecting the scan line SL, and a driving voltage line PL. According to some embodiments, the scan line SL may extend in a first direction (x-axis direction), and the data line DL and the driving voltage line PL may extend in a second direction (y-axis direction).

According to driving of the pixel circuit PC, each pixel P may emit light and the display area DA may display iamges through light emitted from the pixels P. As described above, herein, the pixel P may be defined as an emission area emitting any one of red light, green light, blue light, and white light.

The peripheral area PA may be an area in which the pixels PX are not arranged and may not display images. A printed circuit board including an internal driving circuit unit, a power supply line, and a driving circuit unit for driving the pixels P or a terminal unit to which a driver IC is connected may be arranged in the peripheral area PA.

An organic light emitting diode OLED, which is a display element of the pixel P, may be connected to the pixel circuit PC. The pixel circuit PC may include a first thin film transistor T1, a second thin film transistor T2, and a storage capacitor Cst. For example, the organic light emitting diode OLED may emit red, green, or blue light or may emit red, green, blue, or white light.

As a switching thin film transistor, the second thin film transistor T2 may be connected to the scan line SL and the data line DL and may be configured to transmit a data voltage input from the data line DL to the first thin film transistor T1 according to a switching voltage input from the scan line SL. The storage capacitor Cst may be connected to the second thin film transistor T2 and the driving voltage line PL and may be configured to store a voltage corresponding to the difference between a voltage received from the second thin film transistor T2 and a first power voltage ELVDD supplied to the driving voltage line PL.

As a driving thin film transistor, the first thin film transistor T1 may be connected to the driving voltage line PL and the storage capacitor Cst and may be configured to control a driving current flowing from the driving voltage line PL through the organic light emitting diode OLED in response to a voltage value stored in the storage capacitor Cst. The organic light emitting diode OLED may emit light with a certain brightness according to the driving current. An opposite electrode (e.g., a cathode) of the organic light emitting diode OLED may be supplied with a second power voltage ELVSS.

FIG. 3 illustrates that the pixel circuit PC includes two transistors T1 and T2 and one storage capacitor Cst. However, this is merely an example and the number, arrangement, and type of transistors and storage capacitors may be variously modified according to the design requirements.

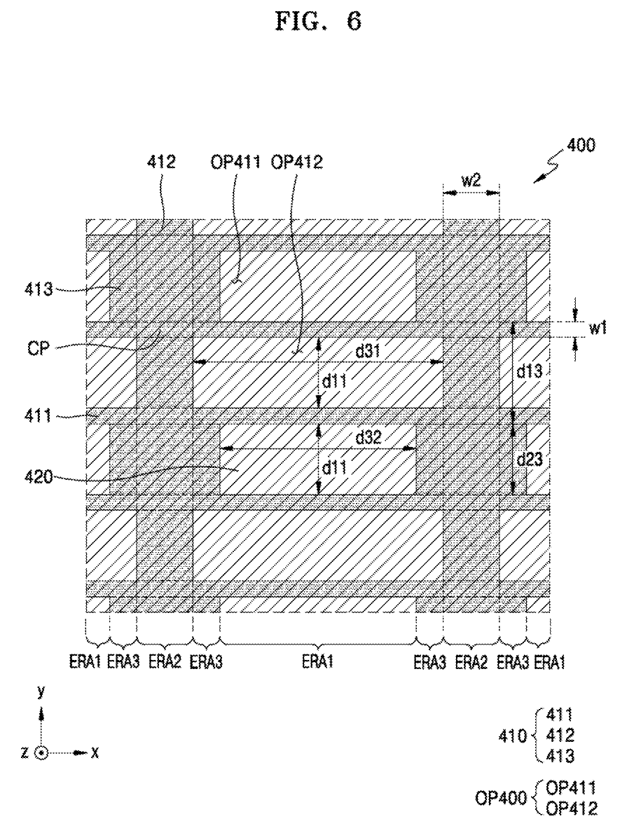

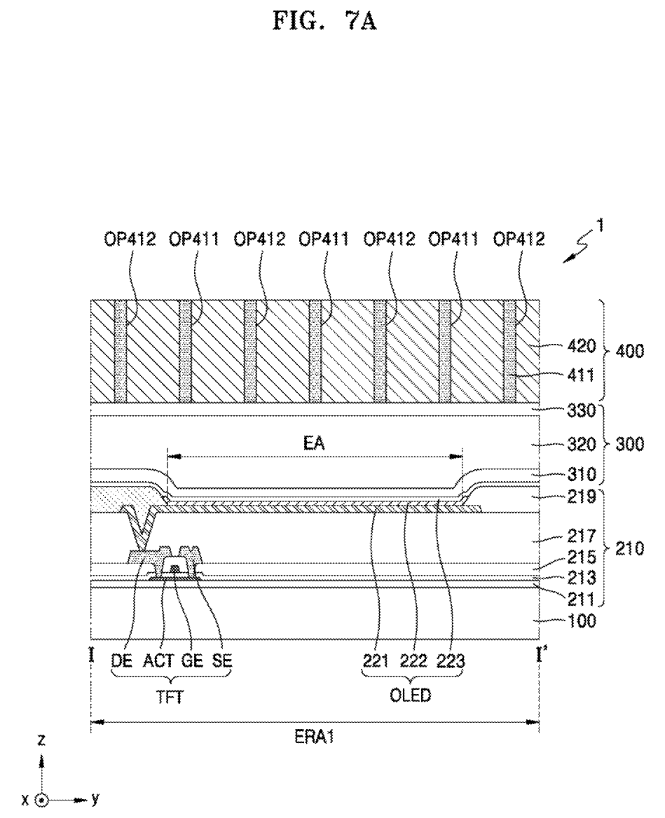

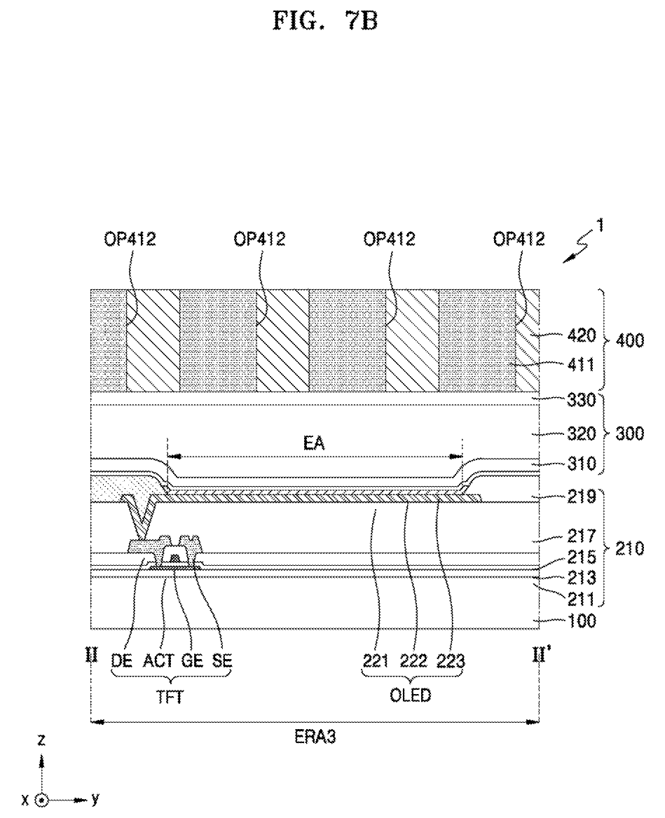

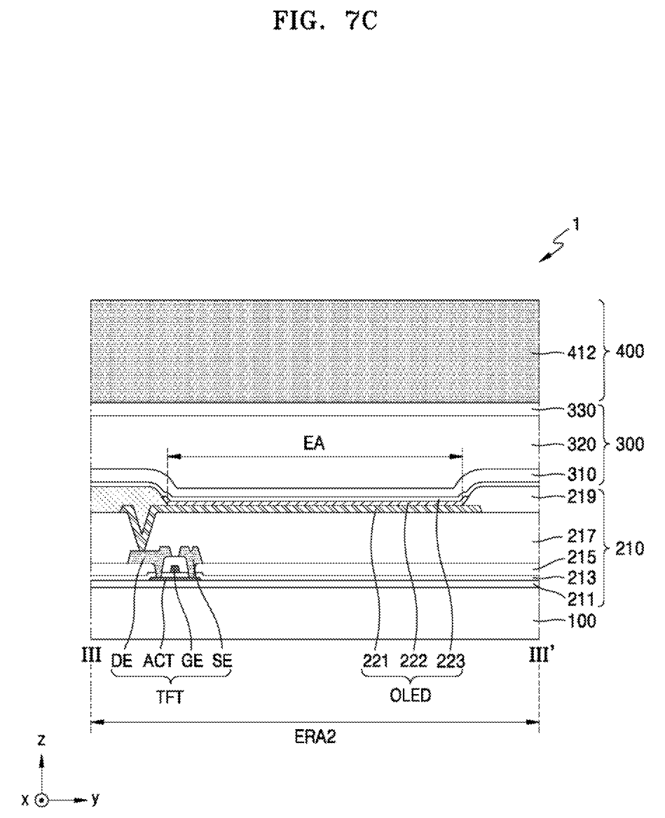

FIGS. 5 and 6 are plan views schematically illustrating the display apparatus 1 according to some embodiments.

Particularly, FIG. 5 is an enlarged view of the display apparatus 1 with respect to region B of FIG. 4, and FIG. 6 is an enlarged view of the display apparatus 1 with respect to region C of FIG. 5.

Referring to FIGS. 5 and 6, the pixel layer 200 (see FIG. 2) including a first pixel P1, a second pixel P2, and a third pixel P3 may be arranged over the substrate 100. Here, the first pixel P1, each of the second pixel P2, and the third pixel P3 illustrated in FIG. 5 may be defined by the emission area of each display element.

The first pixel P1 may emit light of a first wavelength band. For example, the first pixel P1 may emit light with a wavelength of 450 nanometers (nm) (or about 450 nm) to 495 nm (or about 495 nm). The second pixel P2 may emit light of a second wavelength band. For example, the second pixel P2 may emit light with a wavelength of 630 nm (or about 630 nm) to 780 nm (or about 780 nm). The third pixel P3 may emit light of a third wavelength band. For example, the third pixel P3 may emit light with a wavelength of 495 nm (or about 495 nm) to 570 nm (or about 570 nm).

The first pixel P1, the second pixel P2, and the third pixel P3 may have a tetragonal shape among polygonal shapes. Herein, the polygonal shape or the tetragonal shape may also include a shape with rounded corners. That is, the first pixel P1, the second pixel P2, and the third pixel P3 may have a shape with rounded corners. According to some embodiments, the first pixel P1, the second pixel P2, and the third pixel P3 may have a circular shape or an elliptical shape.

The sizes of the first pixel P1, the second pixel P2, and the third pixel P3 may be different from each other. For example, the area of the second pixel P2 may be less than the area of each of the first pixel P1 and the third pixel P3, and the area of the first pixel P1 may be greater than the area of the third pixel P3. However, embodiments according to the present disclosure are not limited thereto. Various modifications may be possible, such as the sizes of the first pixel P1, the second pixel P2, and the third pixel P3 being equal (or substantially equal) to each other.

The first pixel P1 may be provided as a plurality of first pixels P1, which may be arranged apart from each other in the first direction (e.g., x-axis direction). The second pixel P2 and the third pixel P3 may each be provided as a plurality of second pixels P2 and a plurality of third pixels P2, which may be repeatedly arranged apart from each other in the first direction (e.g., x-axis direction). A pixel row formed by a plurality of first pixels P1 arranged in the first direction (e.g., x-axis direction) and a pixel row formed by second pixels P2 and third pixels P3 alternately arranged in the first direction (e.g., x-axis direction) may be repeatedly arranged spaced apart from each other in the second direction (e.g., y-axis direction). However, embodiments according to the present disclosure are not limited thereto, and the first pixel P1, the second pixel P2, and the third pixel P3 may be arranged in various pixel arrangement structures such as a pentile (PenTile^{TM}) structure, a stripe structure, a mosaic structure, or a delta structure.

A shading unit 400 may be arranged over the pixel layer 200 (see FIG. 2). The shading unit 400 may restrict a particular-direction component of light emitted from the first pixel P1, the second pixel P2, and the third pixel P3. For example, when a second-direction (e.g., y-axis direction) component of the light emitted from the first pixel P1, the second pixel P2, and the third pixel P3 exceeds a certain value and has an emission angle greater than or equal to a cut-off angle, the emitted light may be blocked by the shading unit 400. Thus, the viewing angle of the display apparatus 1 in the second direction (e.g., y-axis direction) may be restricted such that light emitted from the display apparatus 1 does not obstruct the driver's view by being reflected by a vehicle window or the like. The shading unit 400 may include a shading wall 410, a plurality of shading openings OP400 arranged in the shading wall 410, and a transparent layer 420 accommodated in the shading openings OP400.

The shading wall 410 may absorb a portion of the light emitted from the first pixel P1, the second pixel P2, and the third pixel P3. The shading wall 410 may include a low-reflective material. For example, the shading wall 410 may include a metal oxide. According to some embodiments, the metal oxide may include at least one of molybdenum tantalum oxide (Mo-Ta-O (MTO)), copper oxide (CuO), calcium oxide (CaO), molybdenum oxide (MoOₓ), or zinc oxide (ZnO). According to some embodiments, the shading wall 410 may have a multilayer structure. For example, the shading wall 410 may have a structure in which metal oxide layers and metal layers are alternately stacked. According to some embodiments, the shading wall 410 may have a multilayer structure in which an MTO layer/a Mo layer/an MTO layer are stacked, or may have a multilayer structure in which an MTO layer/an Al layer/an MTO layer are stacked.

The shading wall 410 may include a plurality of first shading walls 411, a plurality of second shading walls 412, and a plurality of third shading walls 413. For example, the plurality of first shading walls 411, the plurality of second shading walls 412, and the plurality of third shading walls 413 may include the same material.

The plurality of first shading walls 411 may extend in the first direction (e.g., x-axis direction) and may be spaced apart from each other in the second direction (e.g., y-axis direction). In the plan view, the plurality of first shading walls 411 may have a stripe pattern. For example, the plurality of first shading walls 411 may be arranged at equal intervals in the second direction (e.g., y-axis direction). However, this is merely an example, and the arrangement of the plurality of first shading walls 411 is not limited thereto.

The plurality of second shading walls 412 may extend in the second direction (e.g., y-axis direction) and may be spaced apart from each other in the first direction (e.g., x-axis direction). In the plan view, the plurality of second shading walls 412 may have a stripe pattern. For example, the plurality of second shading walls 412 may be arranged at equal intervals in the first direction (e.g., x-axis direction). However, this is merely an example, and the arrangement of the plurality of second shading walls 412 is not limited thereto.

The plurality of first shading walls 411 and the plurality of second shading walls 412 may intersect each other at a plurality of intersection portions CP. In the plan view, the plurality of first shading walls 411 and the plurality of second shading walls 412 may have a grid-type pattern. For example, the plurality of intersection portions CP may be arranged at equal intervals in the first direction (e.g., x-axis direction) and the second direction (e.g., y-axis direction). However, this is merely an example, and the arrangement of the plurality of intersection portions CP is not limited thereto.

The plurality of third shading walls 413 may protrude from the first shading walls 411 in the first direction (e.g., x-axis direction). The plurality of third shading walls 413 may be spaced apart from each other in the first direction (e.g., x-axis direction) and the second direction (e.g., y-axis direction). Some of the plurality of shading openings OP400 may not contact the third shading walls 413. Some of the plurality of shading openings OP400 may be surrounded by the plurality of first shading walls 411 and the plurality of second shading walls 412. Some others of the plurality of shading openings OP400 may contact the third shading walls 413. Some others of the plurality of shading openings OP400 may be surrounded by the plurality of first shading walls 411 and the plurality of third shading walls 413.

The plurality of shading openings OP400 may pass through the shading wall 410 and may include a plurality of first shading openings OP411 and a plurality of second shading openings OP412. The plurality of first shading openings OP411 may be arranged between the plurality of first shading walls 411 and the plurality of third shading walls 413. In the plan view, the plurality of first shading openings OP411 may be surrounded by the plurality of first shading walls 411 and the plurality of third shading walls 413. The plurality of second shading openings OP412 may be arranged between the plurality of first shading walls 411 and the plurality of second shading walls 412. In the plan view, the plurality of second shading openings OP412 may be surrounded by the plurality of first shading walls 411 and the plurality of second shading walls 412.

The plurality of first shading openings OP411 may be arranged apart from each other in the first direction (e.g., x-axis direction). The plurality of second shading openings OP412 may be arranged apart from each other in the first direction (e.g., x-axis direction). A plurality of first shading openings OP411 may be arranged in one row, and a plurality of second shading openings OPb may be arranged in another row. The plurality of first shading openings OP411 and the plurality of second shading openings OP412 may be alternately arranged in the second direction (e.g., y-axis direction). A plurality of first shading openings OP411 and a plurality of second shading openings OP412 may be alternately arranged in one column.

In this case, a thickness w2 of each of the plurality of second shading walls 412 may be greater than a thickness w1 of each of the plurality of first shading walls 411. In this structure, the plurality of second shading walls 412 may efficiently support the plurality of first shading walls 411. Thus, the durability of the shading unit 400 may be relatively improved.

A distance d13 between two third shading walls 413 arranged adjacent to each other in the second direction (e.g., y-axis direction) may be greater than a distance d11 between two first shading walls 411 arranged adjacent to each other in the second direction (e.g., y-axis direction). The distance d11 between two first shading walls 411 arranged adjacent to each other in the second direction (e.g., y-axis direction) may be equal to a length d23 of each of the plurality of third shading walls 413 in the second direction (e.g., y-axis direction). A length d31 of each of the plurality of second shading openings OP412 in the first direction (e.g., x-axis direction) may be greater than a length d32 of each of the plurality of first shading openings OP411 in the first direction (e.g., x-axis direction). In this structure, in the plan view, the plurality of second shading walls 412 and the plurality of third shading walls 413 may have a zipper shape.

The substrate 100 may include a shading area SHA and a transmission area TA that reflect or absorb the light emitted from the first pixel P1, the second pixel P2, and the third pixel P3. In the plan view, an area in which the shading walls 410 overlap each other may be defined as a shading area SHA. A transmission area TA through which light emitted from the organic light emitting diode OLED may be transmitted may be located between adjacent shading areas SHA. As illustrated in FIG. 5, one emission area EA may overlap a plurality of shading areas SHA and a plurality of transmission areas TA. When a second-direction (e.g., y-axis direction) component of the light emitted from the organic light emitting diode OLED exceeds a certain value and has an emission angle greater than or equal to a cut-off angle, the emitted light may be absorbed by the shading wall 410.

The transparent layer 420 may be accommodated in each of the plurality of first shading openings OP411 and the plurality of second shading openings OP412. In the plan view, the transparent layer 420 may be surrounded by the shading wall 410. The transparent layer 420 may have a flat upper surface. The transparent layer 420 may include a transparent organic material. According to some embodiments, the transparent layer 420 may include acryl-based resin (e.g., polymethyl methacrylate or polyacrylic acid), ethylhexyl acrylate, pentafluoropropyl acrylate, polyethylene glycol dimethacrylate, or ethylene glycol dimethacrylate.

FIGS. 7A to 7C are cross-sectional views schematically illustrating a display apparatus 1 according to some embodiments.

Particularly FIG. 7A is a cross-sectional view of the display apparatus 1 taken along the line I-I' of FIG. 5, FIG. 7B is a cross-sectional view of the display apparatus 1 taken along the line II-II' of FIG. 5, and FIG. 7C is a cross-sectional view of the display apparatus 1 taken along the line III-III' of FIG. 5.

Referring to FIGS. 5 to 7C, the substrate 100 may include a plurality of first areas ERA1, a plurality of second areas ERA2, and a plurality of third areas ERA3.

The plurality of first areas ERA1 may extend in the second direction (e.g., y-axis direction) and may be spaced apart from each other in the first direction (e.g., x-axis direction). In the plan view, the plurality of first areas ERA1 may have a stripe pattern. For example, the plurality of first areas ERA1 may be arranged at equal intervals in the first direction (e.g., x-axis direction). The plurality of second areas ERA2 may extend in the second direction (e.g., y-axis direction) and may be spaced apart from each other in the first direction (e.g., x-axis direction). In the plan view, the plurality of second areas ERA2 may have a stripe pattern. For example, the plurality of second areas ERA2 may be arranged at equal intervals in the first direction (e.g., x-axis direction). The plurality of third areas ERA3 may extend in the second direction (e.g., y-axis direction) and may be spaced apart from each other in the first direction (e.g., x-axis direction). In the plan view, the plurality of third areas ERA3 may have a stripe pattern.

The plurality of third areas ERA3 may be arranged between the plurality of first areas ERA1 and the plurality of second areas ERA2. In the first direction (e.g., x-axis direction), a first area ERA1, a third area ERA3, s second area ERA2, a third area ERA3, and a first area ERA1 may be sequentially arranged.

In the plan view, the plurality of first areas ERA1 may overlap the plurality of first shading walls 411. In the plan view, the plurality of first areas ERA1 may be spaced apart from the plurality of second shading walls 412 and the plurality of third shading walls 413. In the plan view, the plurality of second areas ERA2 may overlap the plurality of first shading walls 411 and the plurality of second shading walls 412. In the plan view, the plurality of second areas ERA2 may overlap the plurality of intersection portions CP. In the plan view, the plurality of second areas ERA2 may be spaced apart from the plurality of third shading walls 413. In the plan view, the plurality of third areas ERAb may overlap the plurality of first shading walls 411 and the plurality of third shading walls 413. In the plan view, the plurality of third areas ERA3 may be spaced apart from the plurality of second shading walls 412.

FIG. 7A illustrates a cross-sectional view of the display apparatus 1 in the first area ERA1 taken in the second direction (e.g., y-axis direction), FIG. 7B illustrates a cross-sectional view of the display apparatus 1 in the third area ERA3 taken in the second direction (e.g., y-axis direction), and FIG. 7C illustrates a cross-sectional view of the display apparatus 1 in the second area ERA2 taken in the second direction (e.g., y-axis direction).

The display apparatus 1 according to some embodiments may include a substrate 100, a pixel circuit layer 210, an organic light emitting diode OLED as a display element, an encapsulation layer 300, and a shading unit 400.

As described above, the substrate 100 may include a glass material or may include a polymer resin. The pixel circuit layer 210 may be arranged over the substrate 100.

The pixel circuit layer 210 may include a thin film transistor TFT and a storage capacitor. The thin film transistor TFT may include a semiconductor layer ACT including amorphous silicon or polycrystalline silicon, or an organic semiconductor material, a gate electrode GE, a source electrode SE, and a drain electrode DE. In order to secure the insulation between the semiconductor layer ACT and the gate electrode GE, a gate insulating layer 213 including an inorganic material such as silicon oxide (SiOₓ), silicon nitride (SiNₓ), and/or silicon oxynitride (SiON) may be arranged between the semiconductor layer ACT and the gate electrode GE.

An interlayer insulating layer 215 including an inorganic material such as silicon oxide (SiOₓ), silicon nitride (SiNₓ), and/or silicon oxynitride (SiON) may be arranged over the gate electrode GE, and the source electrode SE and the drain electrode DE may be arranged over the interlayer insulating layer 215. The insulating layer including the inorganic material may be formed through chemical vapor deposition (CVD) or atomic layer deposition (ALD). According to some embodiments, any one of the source electrode SE and the drain electrode DE may be omitted and replaced with a conductive semiconductor layer ACT.

The gate electrode GE, the source electrode SE, and the drain electrode DE may be formed of various conductive materials. The gate electrode GE may include at least one of molybdenum (Mo), aluminum (Al), copper (Cu), or titanium (Ti) and may have a multilayer structure when necessary. For example, the gate electrode GE may have a single layer of molybdenum (Mo) or may have a three-layer structure including a molybdenum layer, an aluminum layer, and a molybdenum layer. The source electrode SE and the drain electrode DE may include at least one of copper (Cu), titanium (Ti), or aluminum (Al) and may have a multilayer structure when necessary. For example, the source electrode SE and the drain electrode DE may have a three-layer structure including a titanium layer, an aluminum layer, and a titanium layer.

A buffer layer 211 including an inorganic material such as silicon oxide (SiOₓ), silicon nitride (SiNₓ), and/or silicon oxynitride (SiON) may be arranged between the thin film transistor TFT and the substrate 100. The buffer layer 211 may function to increase the smoothness of the upper surface of the substrate 100 or to prevent, reduce, or minimize the penetration of contaminants or impurities into the semiconductor layer ACT of the thin film transistor TFT from the substrate 100 or the like.

A planarization insulating layer 217 may be arranged over the thin film transistor TFT. The planarization insulating layer 217 may be formed of, for example, an organic material such as acryl, benzocyclobutene (BCB), or hexamethyldisiloxane (HMDSO). In FIGS. 7A to 7C, the planarization insulating layer 217 is illustrated as including a single layer; however, the planarization insulating layer 117 may include multiple layers.

A pixel electrode 221 may be arranged over the planarization insulating layer 217. The pixel electrode 221 may be arranged in each pixel. Pixel electrodes 221 respectively corresponding to adjacent pixels may be arranged apart from each other.

The pixel electrode 221 may be a reflective electrode. According to some embodiments, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof, and a transparent or semitransparent electrode layer formed over the reflective layer. The transparent or semitransparent electrode layer may include at least one of indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 221 may have a three-layer structure of an ITO layer, an Ag layer, and an ITO layer.

A pixel definition layer 219 may be arranged over the pixel electrode 221. The pixel definition layer 219 may include an opening that exposes the upper surface of each pixel electrode 221. The opening of the pixel definition layer 219 may define an emission area EA of the pixel. The pixel definition layer 219 may cover the edge of the pixel electrode 221 and increase the distance between the edge of the pixel electrode 221 and an opposite electrode 223 to prevent or reduce instances of an arc or the like occurring at the edge of the pixel electrode 221. The pixel definition layer 219 may be formed of an organic insulating material such as polyimide, polyamide, acrylic resin, benzocyclobutene, hexamethyldisiloxane (HMDSO), or phenol resin by spin coating or the like. Alternatively, the pixel definition layer 219 may include an inorganic insulating material. Alternatively, the pixel definition layer 219 may have a multilayer structure including an inorganic insulating material and an organic insulating material.

According to some embodiments, the pixel definition layer 219 may include a light blocking material and may be provided in black. The light blocking material may include, for example, a resin or paste including carbon black, carbon nanotube, or black dye, metal particles (e.g., nickel, aluminum, molybdenum, or any alloy thereof), metal oxide particles (e.g., chromium oxide), or metal nitride particles (e.g., chromium nitride).

An emission layer 222 may be arranged over the pixel electrode 221. The emission layer 222 may include an organic material including a fluorescent or phosphorescent material capable of emitting red, green, or blue light. The above organic material may include a low-molecular weight organic material or a high-molecular weight organic material. The emission layer 222 may be arranged to correspond to the pixel electrode 221.

A first common layer and/or a second common layer may be respectively arranged under and over the emission layer 222. The first common layer may be a component arranged under the emission layer 222 and may include, for example, a hole transport layer (HTL) or may include an HTL and a hole injection layer (HIL). The second common layer may be a component arranged over the emission layer 222 and may include an electron transport layer (ETL) and/or an electron injection layer (EIL). According to some embodiments, the second common layer may be omitted.

Each of the first common layer and the second common layer may be a common layer integrally formed to entirely cover the substrate 100, for example, to entirely cover the display area of the substrate 100, like the opposite electrode 223 described below.

The opposite electrode 223 may be a cathode that is an electron injection electrode, and in this case, a metal, an alloy, an electrically conductive compound, or any combination thereof having a low work function may be used as the material for the opposite electrode 223. The opposite electrode 223 may be a transparent electrode, a semitransparent electrode, or a reflective electrode.

The opposite electrode 223 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or any combination thereof. The opposite electrode 223 may have a single-layer structure including a single layer or a multilayer structure including a plurality of layers.

A capping layer may be further arranged over the opposite electrode 223. The capping layer may function to relatively improve the external light emission efficiency of the organic light emitting diode OLED according to the principle of constructive interference. The capping layer may include a material having a refractive index of 1.6 or more (at 589 nm). The thickness of the capping layer may be 1 nm (or about 1 nm) to 200 nm (or about 200 nm), for example, 5 nm (or about 5 nm) to 150 nm (or about 150 nm), or 10 nm (or about 10 nm) to 100 nm (or about 100 nm). The capping layer may be an organic capping layer including an organic material, an inorganic capping layer including an inorganic material, or a composite capping layer including an organic material and an inorganic material.

The encapsulation layer 300 may be arranged over the organic light emitting diode OLED to encapsulate the display element. The encapsulation layer 300 may include at least one inorganic encapsulation layer and at least one organic encapsulation layer. The at least one inorganic encapsulation layer may include one or more inorganic materials among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). The at least one organic encapsulation layer may include a polymer-based material. The polymer-based material may include acryl-based resin, epoxy-based resin, polyimide, polyethylene, or the like. According to some embodiments, the at least one organic encapsulation layer may include acrylate. FIGS. 7A to 7C illustrate that the encapsulation layer 300 includes a first inorganic encapsulation layer 310, a second inorganic encapsulation layer 330, and an organic encapsulation layer 320 arranged between the first inorganic encapsulation layer 310 and the second inorganic encapsulation layer 330. The organic encapsulation layer 320 may cover the unevenness of the organic light emitting diode OLED to provide a flat upper surface thereof.

The shading unit 400 may be arranged over the encapsulation layer 300. The shading unit 400 may include a shading wall 410, a plurality of shading openings OP400, and a transparent layer 420. The shading wall 410 may include a plurality of first shading walls 411, a plurality of second shading walls 412, and a plurality of third shading walls 413. The plurality of shading openings OP400 may include a plurality of first shading openings OP411 and a plurality of second shading openings OP412. Because the shading unit 400 has been described above with reference to FIGS. 5 and 6, redundant descriptions of the shading unit 400 will be omitted for conciseness.

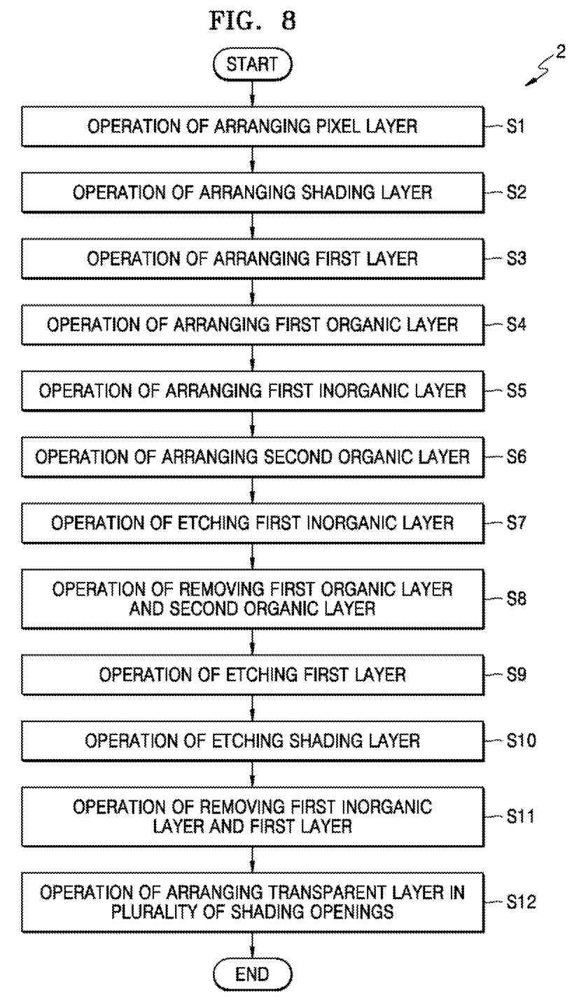

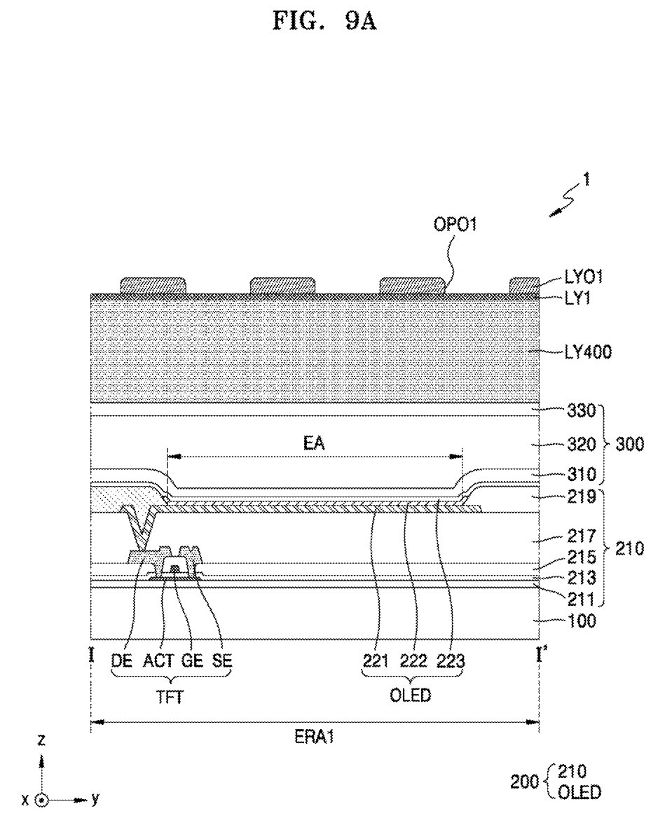

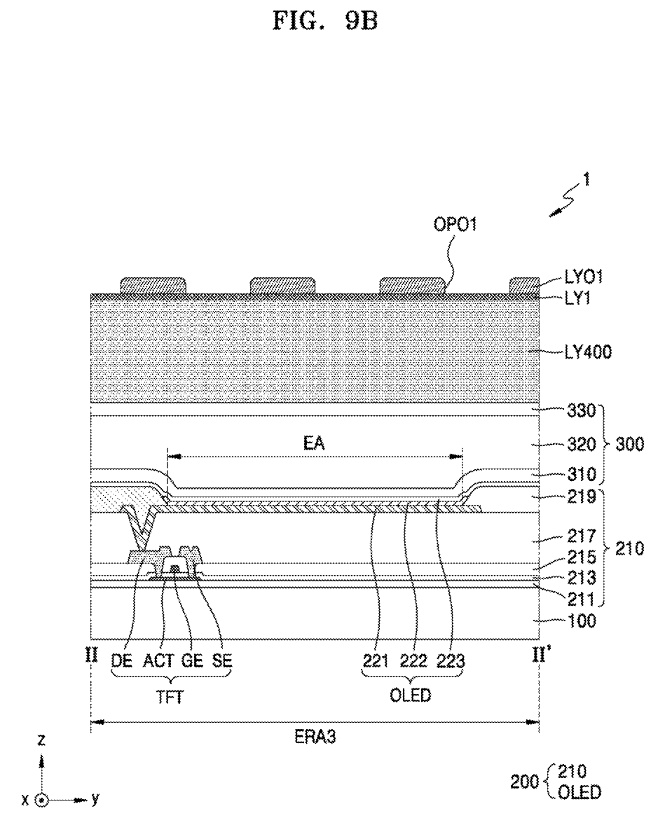

FIG. 8 is a flowchart schematically illustrating a method 2 of manufacturing a display apparatus according to some embodiments. Although FIG. 8 illustrates various operations in a method of manufacturing a display apparatus, embodiments according to the present disclosure are not limited thereto, and according to some embodiments, the method may include additional operations, or fewer operations, or the order of operations may vary, unless otherwise stated or implied, without departing from the spirit and scope of embodiments according to the present disclosure.

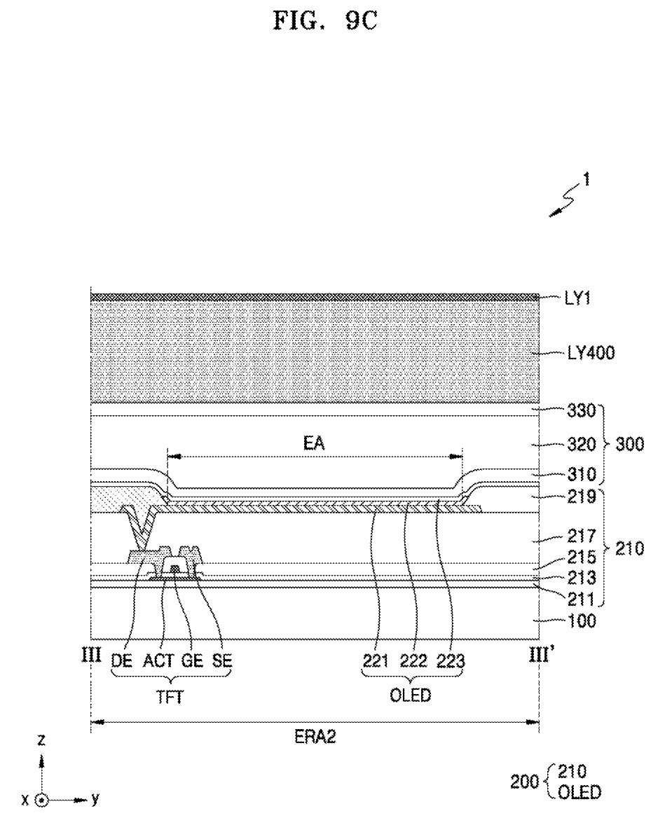

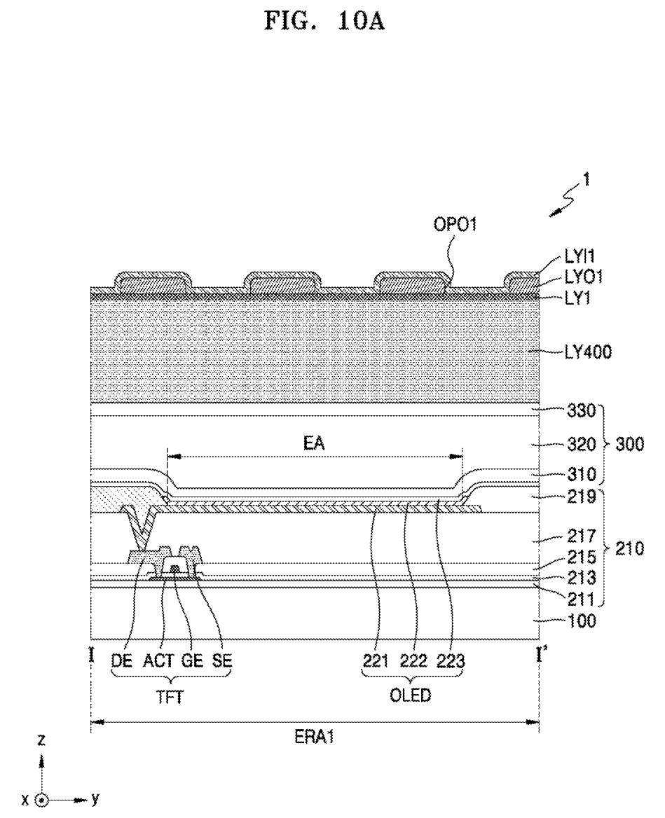

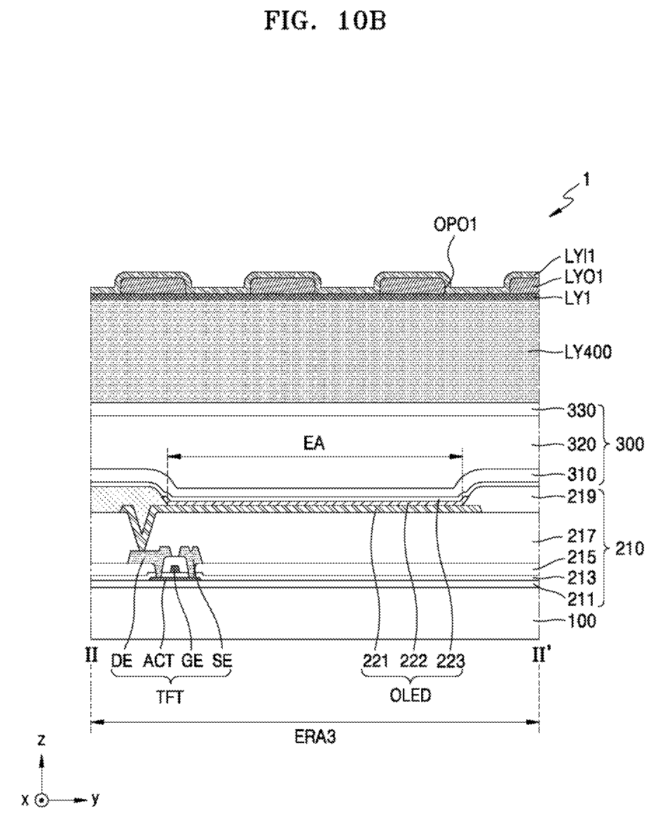

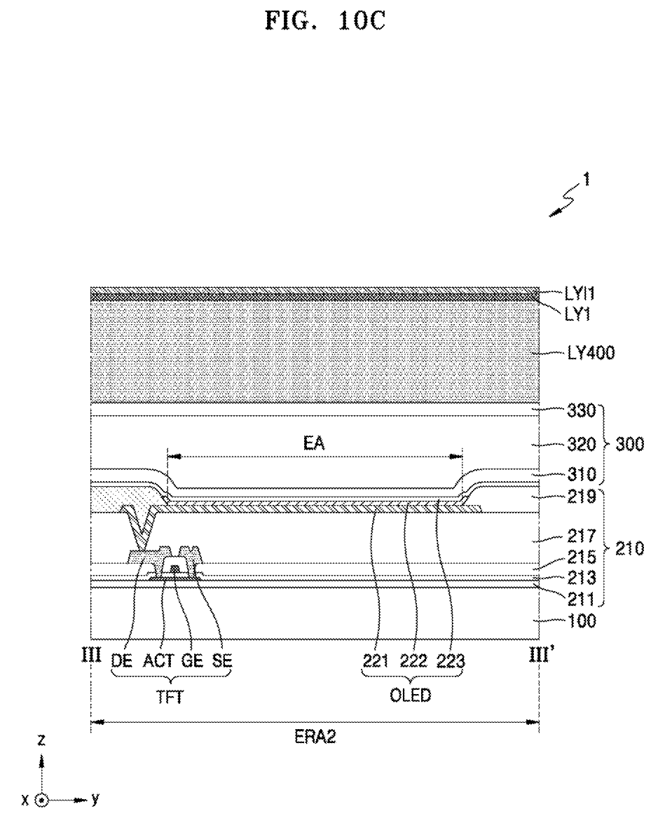

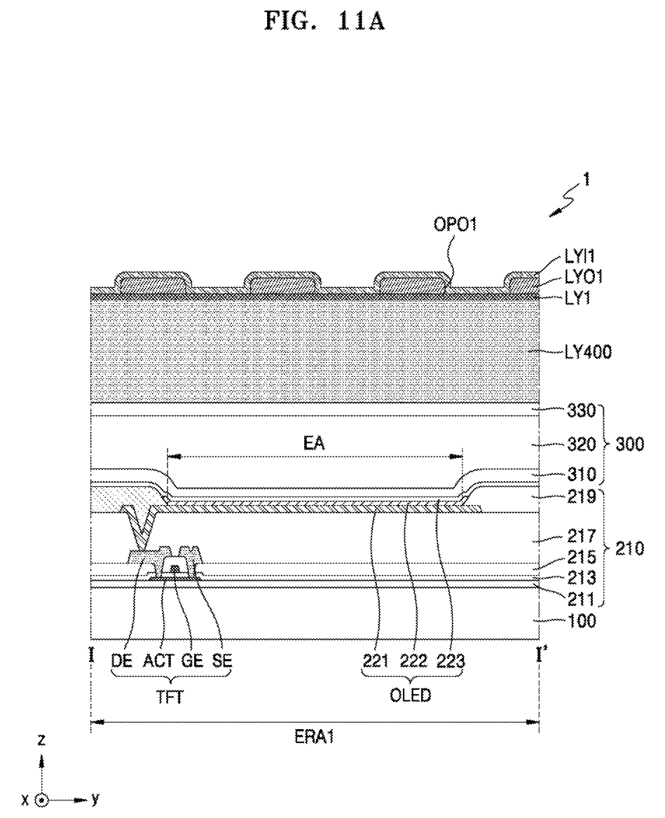

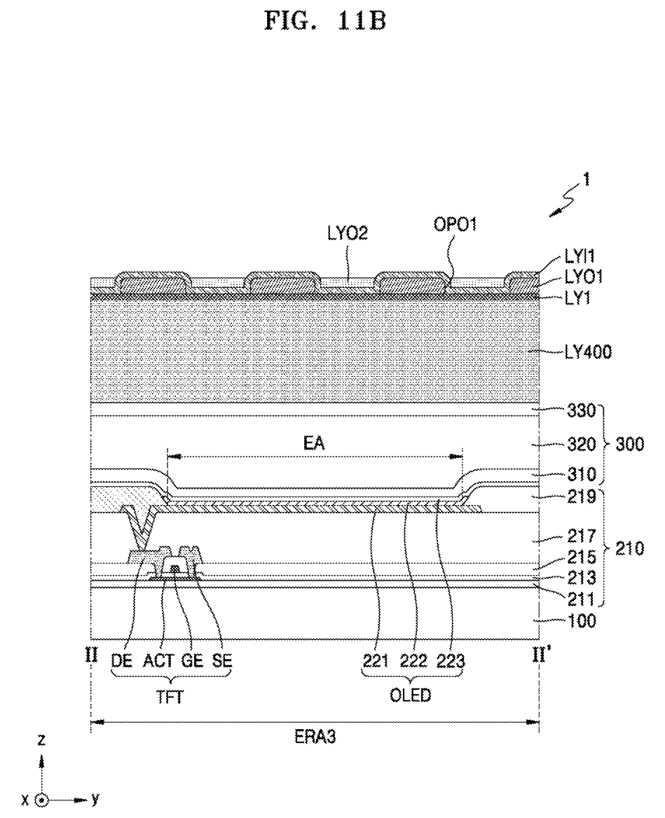

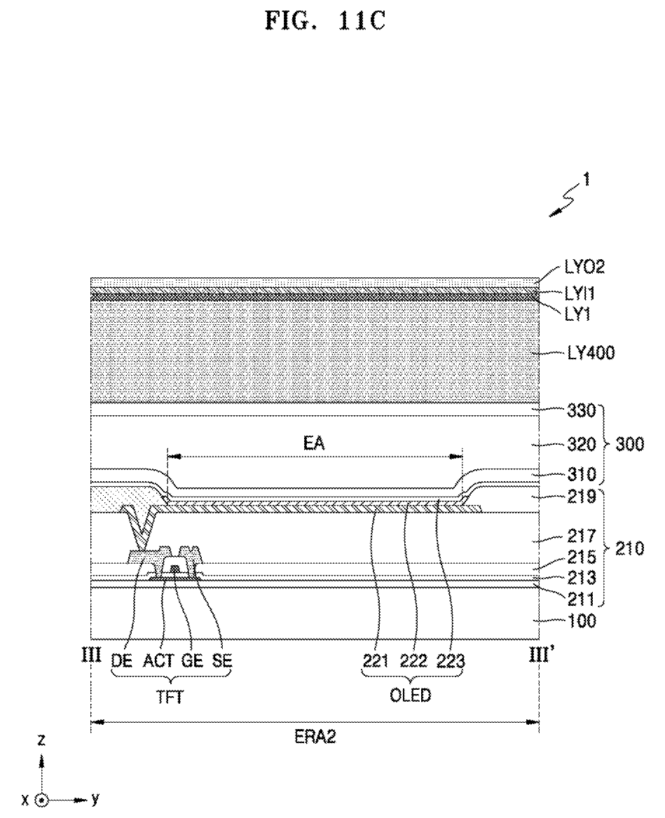

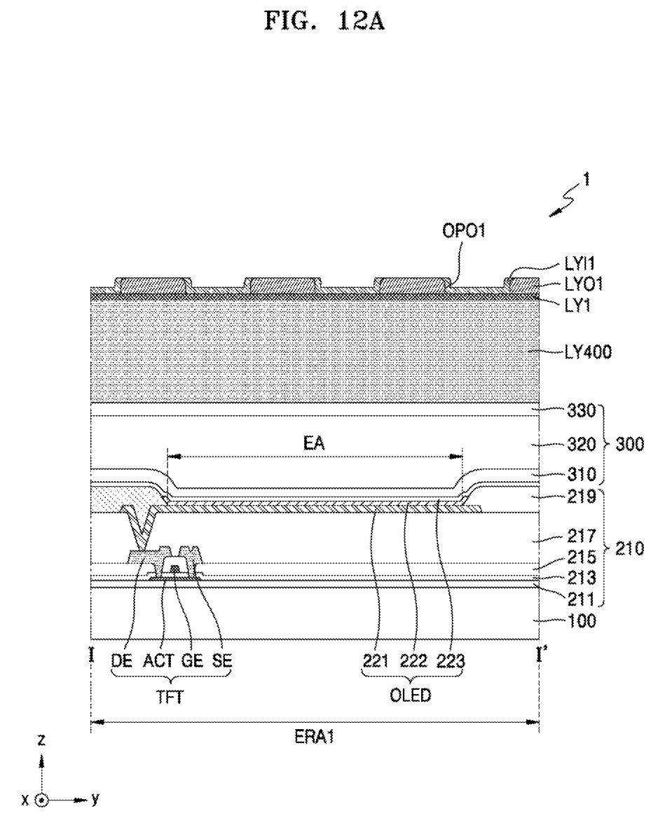

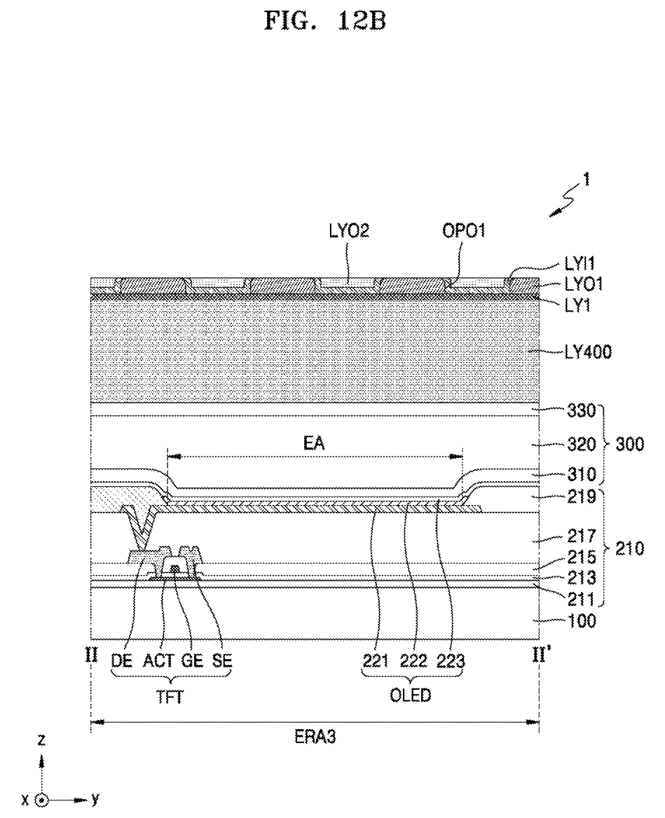

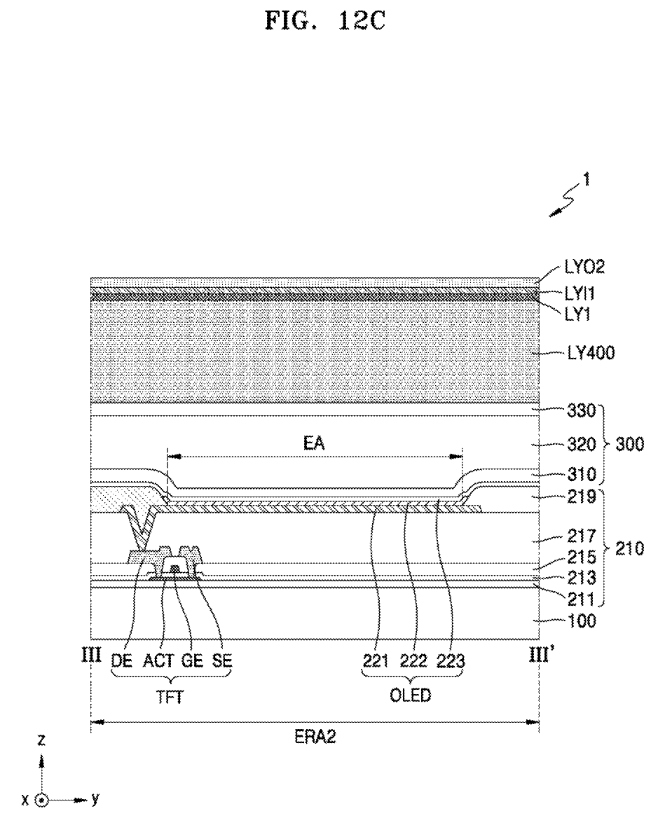

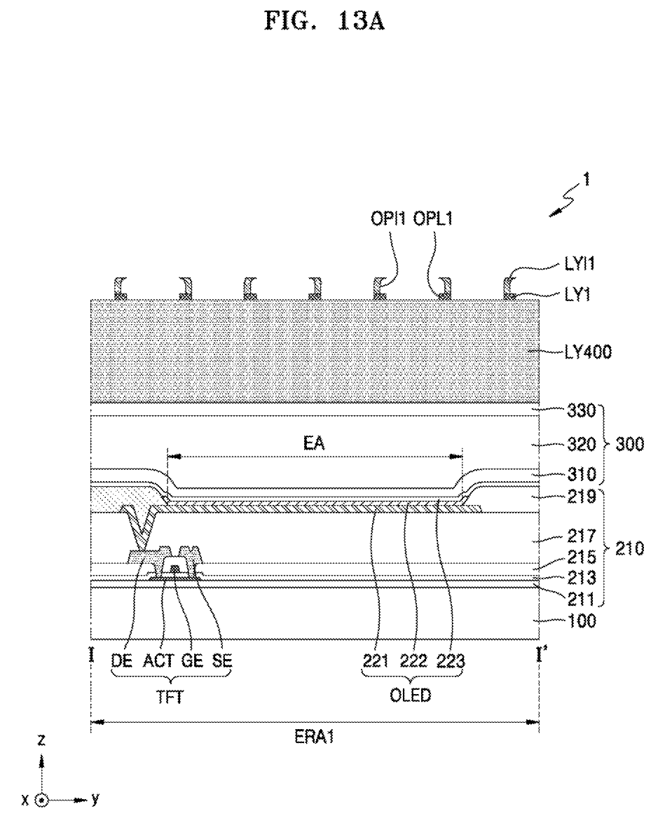

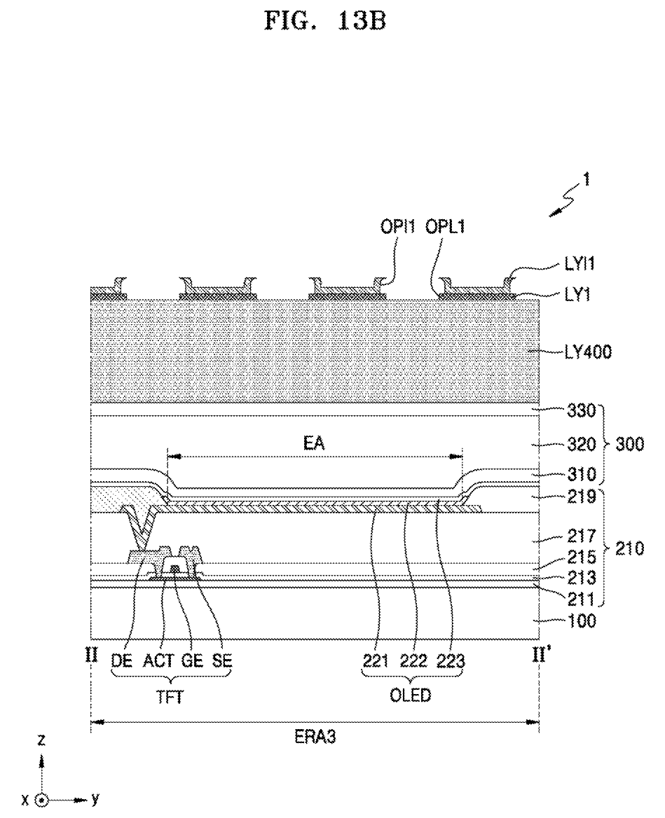

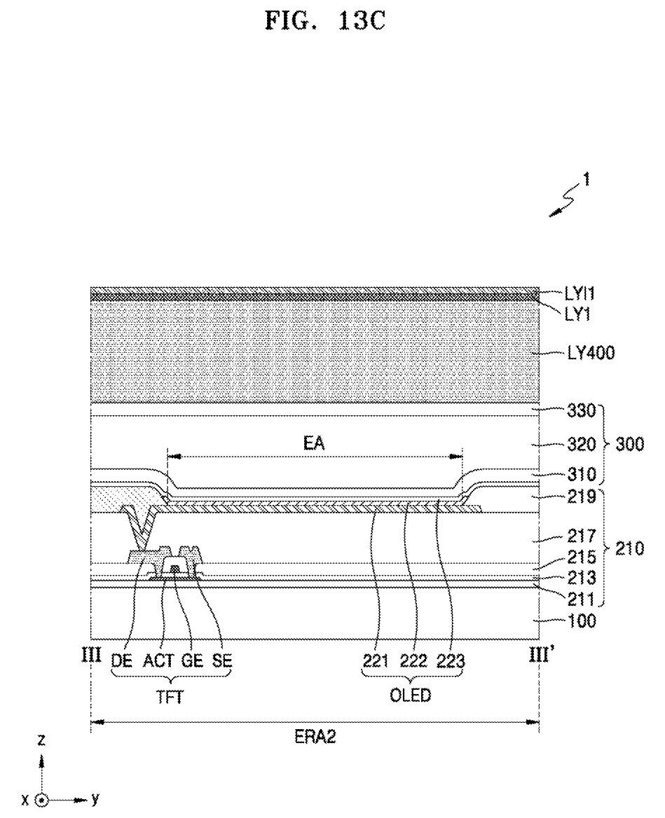

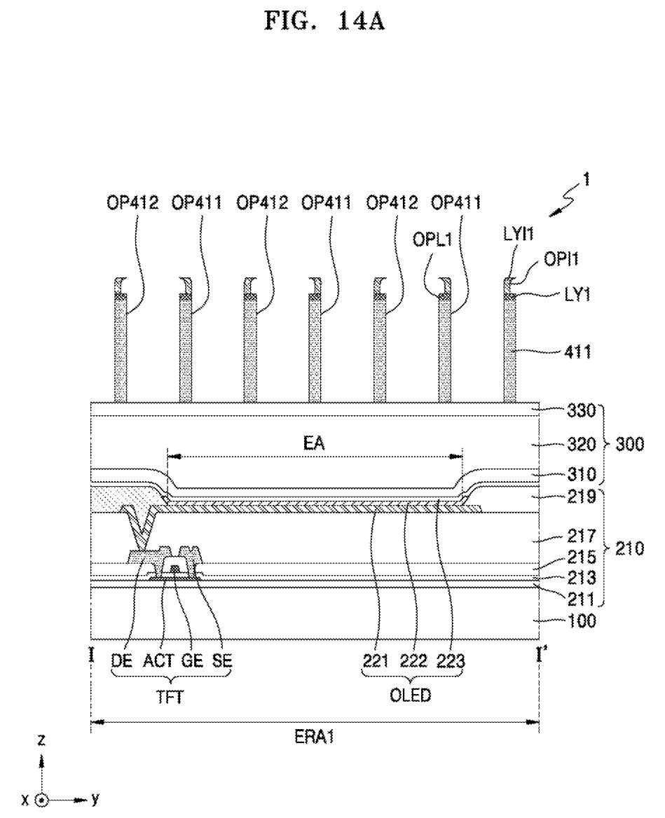

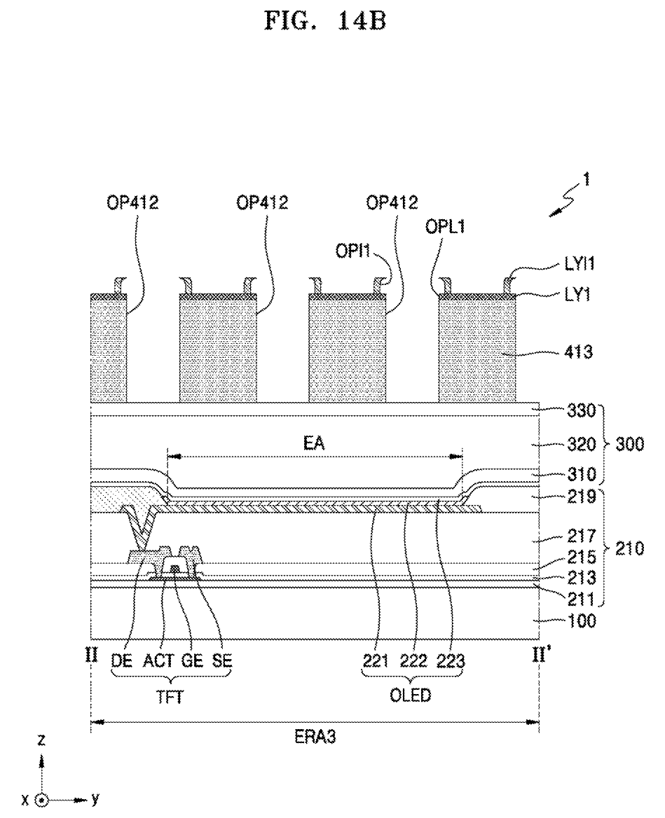

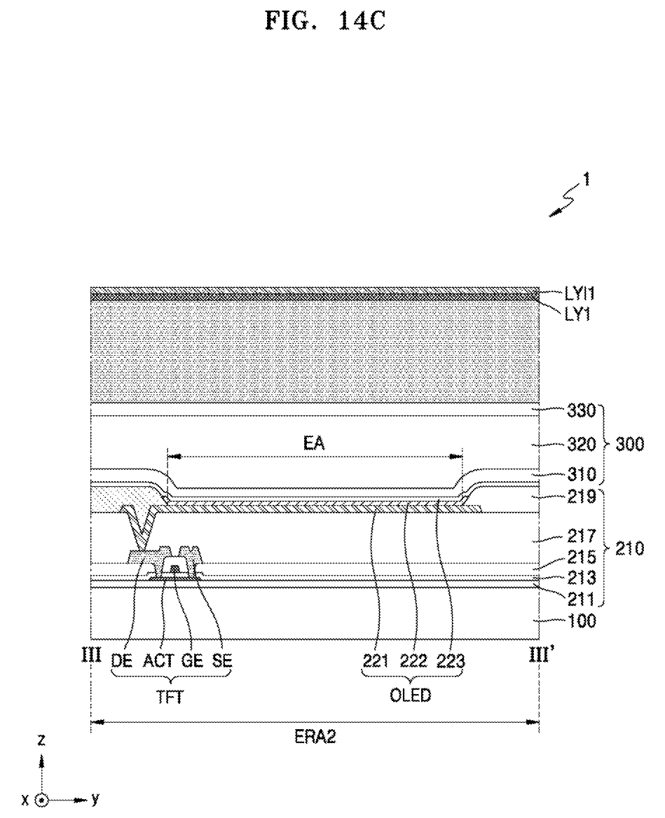

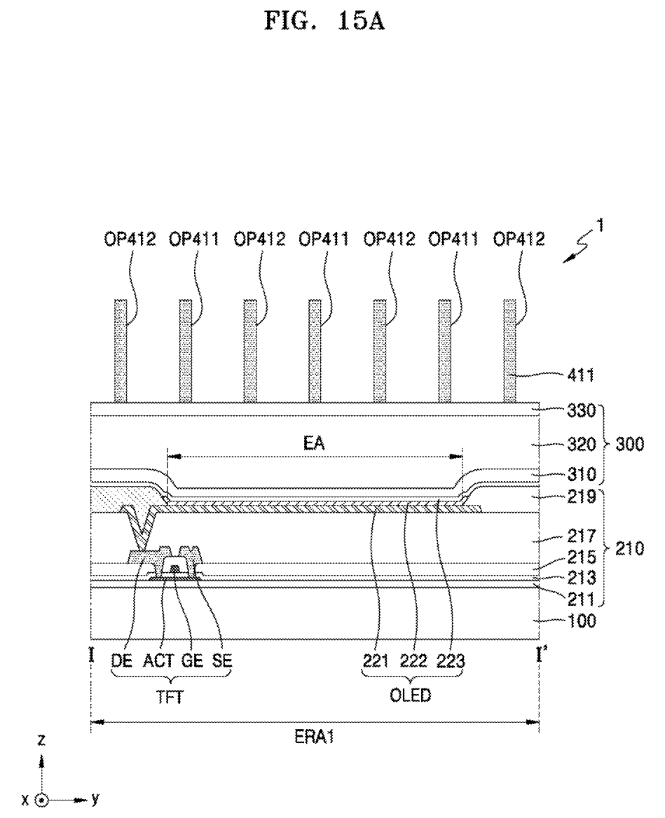

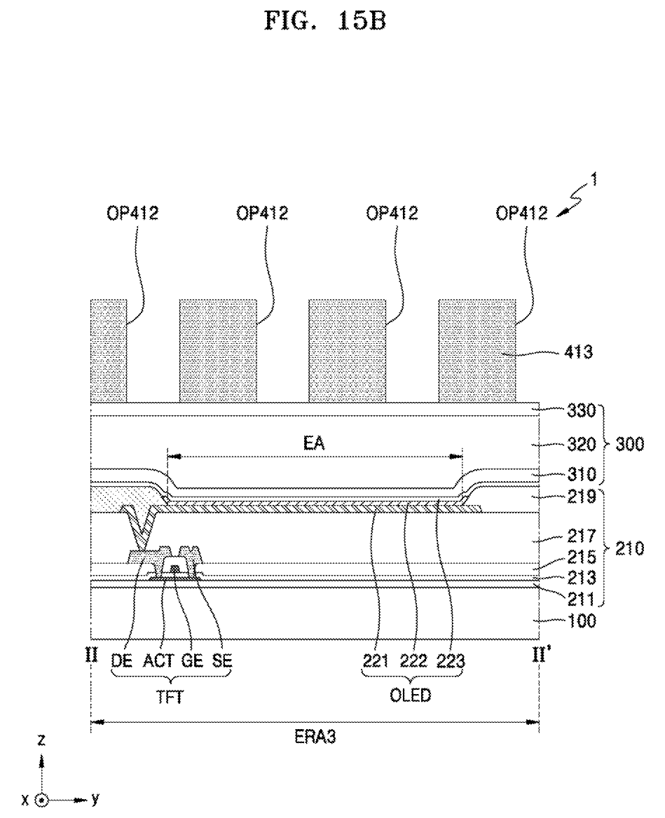

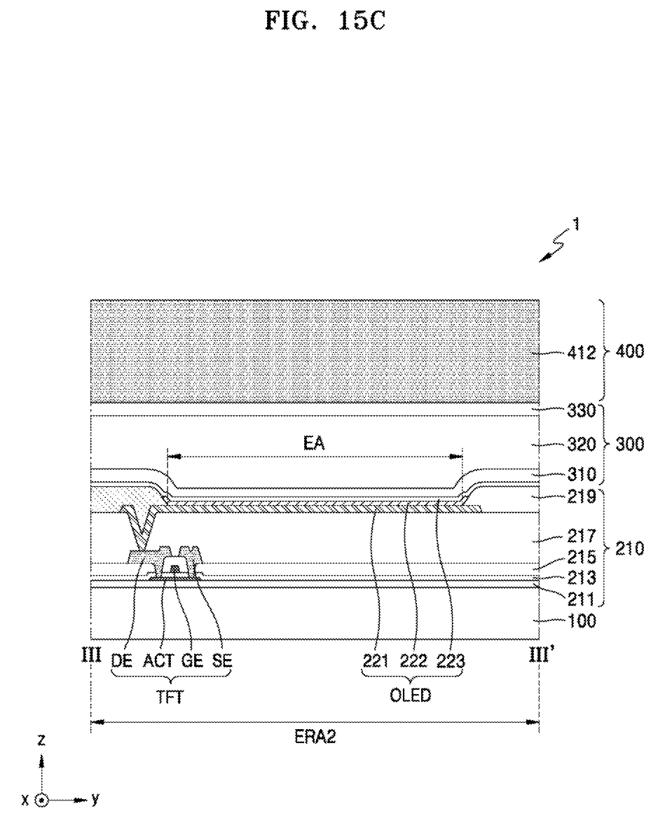

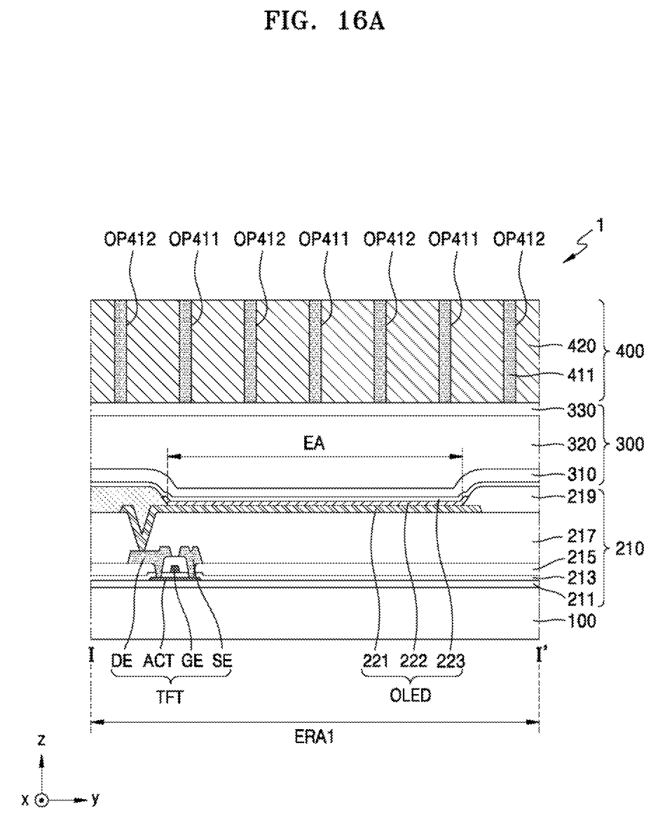

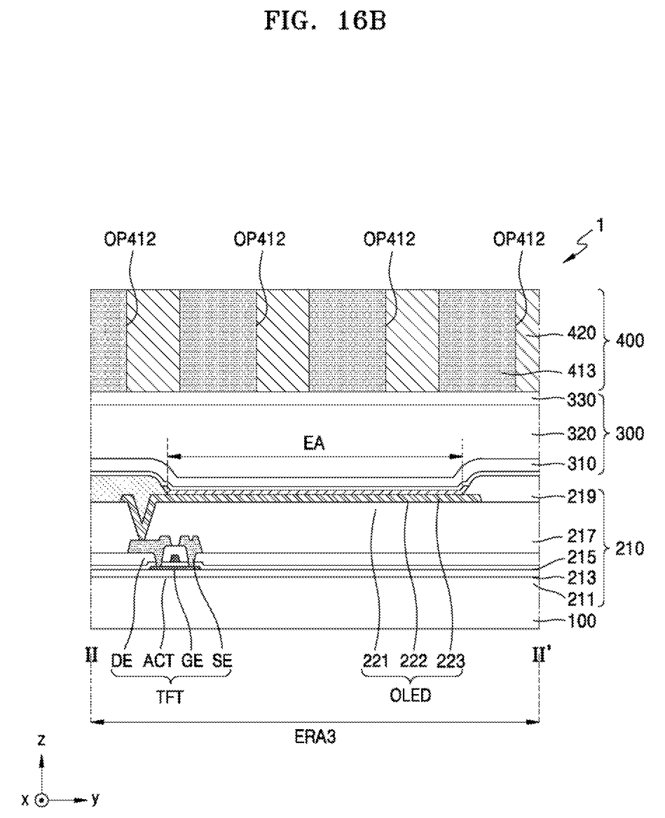

FIGS. 9A to 16C are cross-sectional views schematically illustrating the display apparatus 1 according to some embodiments.

Particularly, FIGS. 9A, 10A, 11A, 12A, 13A, 14A, 15A, and 16A are cross-sectional views of the display apparatus 1 taken along the line I-I' of FIG. 5, and FIGS. 9B, 10B, 11B, 12B, 13B, 14B, 15B, and 16B are cross-sectional views of the display apparatus 1 taken along the line II-II' of FIG. 5, and FIGS. 9C, 10C, 11C, 12C, 13C, 14C, 15C, and 16C are cross-sectional views of the display apparatus 1 taken along the line III-III' of FIG. 5.

FIGS. 9A, 10A, 11A, 12A, 13A, 14A, 15A, and 16A illustrate cross-sectional views of the display apparatus 1 in the first area ERA1 taken in the second direction (e.g., y-axis direction), FIGS. 9B, 10B, 11B, 12B, 13B, 14B, 15B, and 16B illustrate cross-sectional views of the display apparatus 1 in the third area ERA3 taken in the second direction (e.g., y-axis direction), and FIGS. 9C, 10C, 11C, 12C, 13C, 14C, 15C, and 16C illustrate cross-sectional views of the display apparatus 1 in the second area ERA2 taken in the second direction (e.g., y-axis direction).

In FIGS. 8 to 16C, like reference numerals as those in FIGS. 5 to 7C denote like members, and thus, redundant descriptions thereof will be omitted for conciseness.

Referring to FIGS. 6 and 8 to 16C, the method 2 may be understood.

First, referring to FIGS. 6 and 8 to 9C, the method 2 may include an operation S1 of arranging a pixel layer 200 over a substrate 100, an operation S2 of arranging a shading layer LY400 over the pixel layer 200, an operation S3 of arranging a first layer LY1 over the shading layer LY400, and an operation S4 of arranging a first organic layer LYO1 including a first organic opening OPO1 over the first layer LY1.

In the operation S2 of arranging the shading layer LY400, the shading layer LY400 may overlap a plurality of first areas ERA1, a plurality of second areas ERA2, and a plurality of third areas ERA3. The shading layer LY400 may be arranged over an encapsulation layer 300. The shading layer LY400 may cover the front surface of the substrate 100. The shading layer LY400 may be arranged flat over the encapsulation layer 300.

In the operation S3 of arranging the first layer LY1, the first layer LY1 may overlap the plurality of first areas ERA1, the plurality of second areas ERA2, and the plurality of third areas ERA3. The first layer LY1 may cover the front surface of the shading layer LY400. The first layer LY1 may be arranged flat over the shading layer LY400. For example, the first layer LY1 may include a Ti material.

In the operation S4 of arranging the first organic layer LYO1, the first organic layer LYO1 may overlap the plurality of first areas ERA1 and the plurality of third areas ERA3. The first organic layer LYO1 may not overlap the plurality of second areas ERA2. The first organic layer LYO1 including the first organic opening OPO1 may be patterned by a known photolithography process.

For example, the first organic layer LYO1 may include acryl-based resin (e.g., polymethyl methacrylate or polyacrylic acid), ethylhexyl acrylate, pentafluoropropyl acrylate, polyethylene glycol dimethacrylate, and/or ethylene glycol dimethacrylate.

Referring to FIGS. 6, 8, and 10A to 10C, the method 2 may include an operation S5 of arranging a first inorganic layer LYI1 over the first layer LY1.

In the operation S5 of arranging the first inorganic layer LYI1, the first inorganic layer LYI1 may overlap the plurality of first areas ERA1, the plurality of second areas ERA2, and the plurality of third areas ERA3. The first inorganic layer LYI1 may cover the front surface of the first layer LY1. In the plurality of first areas ERA1 and the plurality of third areas ERA3, the first inorganic layer LYI1 may cover the first organic layer LYO1. In the plurality of first areas ERA1 and the plurality of third areas ERA3, at least a portion of the first inorganic layer LYI1 may be accommodated in the first organic opening OPO1 to contact the first layer LY1. In the plurality of second areas ERA2, the first inorganic layer LYI1 covering the first layer LY1 may be arranged flat. For example, the first inorganic layer LYIb may include an inorganic material such as silicon oxide (SiOₓ), silicon nitride (SiNₓ), and/or silicon oxynitride (SiON).

Referring to FIGS. 6, 8, and 11A to 11C, the method 2 may include an operation S6 of arranging a second organic layer LYO2 over the first inorganic layer LYI1.

In the operation S6 of arranging the second organic layer LYO2, the second organic layer LYO2 may overlap the plurality of second areas ERA2 and the plurality of third areas ERA3. The second organic layer LYO2 may not overlap the plurality of first areas ERA1. In the plurality of third areas ERA3, at least a portion of the second organic layer LYO2 may be accommodated in the first organic opening OPO1 of the first organic layer LYO1. In the plurality of third areas ERA3, the height of the second organic layer LYO2 may be less than or equal to the height of the first organic layer LYO1. Thus, in the plurality of third areas ERA3, at least a portion of the first inorganic layer LYI1 may be exposed from the second organic layer LYO2. In the plurality of second areas ERA2, the second organic layer LYO2 may cover the front surface of the first layer LY1. In the plurality of second areas ERA2, the first inorganic layer LYI1 covering the first layer LY1 may be arranged flat.

The second organic layer LYOb may include the same material as the first organic layer LYO1. For example, the second organic layer LYO2 may include acryl-based resin (e.g., polymethyl methacrylate or polyacrylic acid), ethylhexyl acrylate, pentafluoropropyl acrylate, polyethylene glycol dimethacrylate, and/or ethylene glycol dimethacrylate.

Referring to FIGS. 6, 8, and 12A to 12C, the method 2 may include an operation S7 of etching the first inorganic layer LYI1.

In the operation S7 of etching the first inorganic layer LYIb, in the plurality of first areas ERA1, an upper portion of the first inorganic layer LYI1 may be etched and thus at least a portion of the first organic layer LYO1 may be exposed from the first inorganic layer LYI1.

In the operation S7 of etching the first inorganic layer LYI1, in the plurality of third areas ERA3, at least a portion of the first inorganic layer LYI1 exposed from the second organic layer LYO2 may be etched. In the operation S7 of etching the first inorganic layer LYI1, in the plurality of third areas ERA3, a portion of the first inorganic layer LYI1 may be etched and thus at least a portion of the first organic layer LYO1 may be exposed from the first inorganic layer LYI1.

Thus, in the operation S7 of etching the first inorganic layer LYI1, a first inorganic opening OPI1 may be formed in the first inorganic layer LYI1 arranged in the plurality of first areas ERA1 and the plurality of third areas ERA3. In this case, the first organic layer LYO1 may be accommodated in the first inorganic opening OPI1.

The operation S7 of etching the first inorganic layer LYI1 may be performed by a dry etching process using an etching gas and/or a wet etching process using an etching solution.

Referring to FIGS. 6, 8, and 12A to 13C, the method 2 may include an operation S8 of removing the first organic layer LYO1 and the second organic layer LYO2, and an operation S9 of etching the first layer LY1.

In the operation S8 of removing the first organic layer LYO1 and the second organic layer LYO2, the first organic layer LYO1 may be removed before the second organic layer LYO2, the second organic layer LYO2 may be removed before the first organic layer LYO1, or the first organic layer LYO1 and the second organic layer LYO2 may be simultaneously (or concurrently) removed.

The first organic layer LYO1 and the second organic layer LYO2 may be removed in the plurality of first areas ERA1 and the plurality of third areas ERA3. In the plurality of second areas ERA2, because the first organic layer LYO1 is not arranged, the second organic layer LYO2 may be removed. The operation S8 of removing the first organic layer LYO1 and the second organic layer LYO2 may be performed by a dry etching process using an etching gas and/or a wet etching process using an etching solution.

In the operation S9 of etching the first layer LY1, a first layer opening OPL1 overlapping the first inorganic opening OPI1 may be formed in the first layer LY1. In the operation S9 of etching the first layer LY1, the first inorganic layer LYI1 may function as a mask. Thus, a first inorganic opening OPI1 may be formed in the plurality of first areas ERA1 and the plurality of third areas ERA3. However, in the plurality of second areas ERA2, because the first inorganic layer LYI1 covers the first layer LY1, the first layer LY1 may not be etched. The operation S9 of etching the first layer LY1 may be performed by a dry etching process using an etching gas and/or a wet etching process using an etching solution.

Referring to FIGS. 6, 8, and 14A to 14C, the method 2 may include an operation S10 of etching the shading layer LY400.

In the operation S10 of etching the shading layer LY400, a plurality of shading openings OP400 overlapping the first layer openings OPL1 may be formed in the shading layer LY400. In the operation S10 of etching the shading layer LY400, the first layer LY1 may function as a mask. Thus, a plurality of shading openings OP400 may be formed in the plurality of first areas ERA1 and the plurality of third areas ERA3. Particularly, a plurality of first shading openings OP411 and a plurality of second shading openings OP412 may be formed in the plurality of first areas ERA1, and a plurality of second shading openings OP412 may be formed in the plurality of third areas ERA3. However, in the plurality of second areas ERA2, because the first layer LY1 covers the shading layer LY400, the shading layer LY400 may not be etched.

The shading layer LY400 with the shading opening OP400 formed therein will be referred to as a shading wall 410 described above. The shading wall 410 may include a plurality of first shading walls 411 arranged in the plurality of first areas ERA1, a plurality of third shading walls 413 arranged in the plurality of third areas ERA3, and a plurality of second shading walls 412 arranged in the plurality of second areas ERA2. The operation S10 of etching the shading layer LY400 may be performed by a dry etching process using an etching gas and/or a wet etching process using an etching solution.

Referring to FIGS. 6, 8, and 14A to 15C, the method 2 may include an operation S11 of removing the first inorganic layer LYI1 and the first layer LY1.

In the operation S11 of removing the first inorganic layer LYI1 and the first layer LY1, the first inorganic layer LYI1 may be removed before the first layer LY1, the first layer LY1 may be removed before the first inorganic layer LYI1, or the first inorganic layer LYI1 and the first layer LY1 may be simultaneously (or concurrently) removed. The operation S11 of removing the first inorganic layer LYI1 and the first layer LY1 may be performed by a dry etching process using an etching gas and/or a wet etching process using an etching solution.

Referring to FIGS. 6, 8, and 16A to 16C, the method 2 may include an operation S12 of arranging a transparent layer 420 in the plurality of shading openings OP400. In the operation S12 of arranging the transparent layer 420 in the plurality of shading openings OP400, the transparent layer 420 may be accommodated in the plurality of first shading openings OP411 and the plurality of second shading openings OP412. The transparent layer 420 may be arranged in the plurality of first areas ERA1 and the plurality of third areas ERA3.

The display apparatus 1 according to some embodiments may be applied to various electronic apparatuses. An electronic apparatus according to some embodiments may include the display apparatus 1 described above and may further include modules or devices having other additional functions in addition to the display apparatus 1.

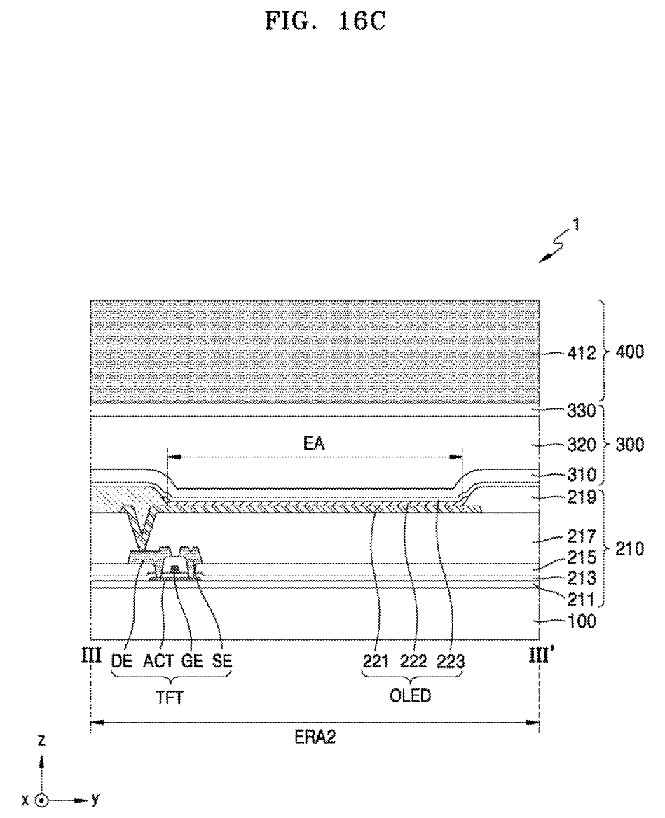

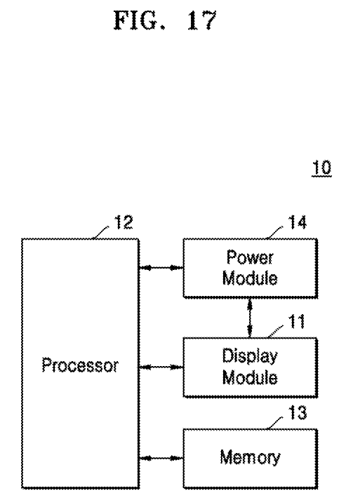

FIG. 17 is a block diagram of an electronic apparatus according to some embodiments. Referring to FIG. 17, an electronic apparatus 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal may be transmitted to the display module 11 and the display module 11 may process the received signal and output image information through a display screen.

The power module 14 may include a power supply module such as a power adapter or a battery device, and a power conversion module that converts the power supplied by the power supply module to generate power necessary for the operation of the electronic apparatus 10.

At least one of the components of the electronic apparatus 10 described above may be included in the display apparatus according to some embodiments described above. Also, some of the individual modules functionally included in one module may be included in the display apparatus, and some others thereof may be provided separately from the display apparatus. For example, the display apparatus may include the display module 11, and the processor 12, the memory 13, and the power module 14 may be provided in the form of other devices in the electronic apparatus 10 that is not the display apparatus.

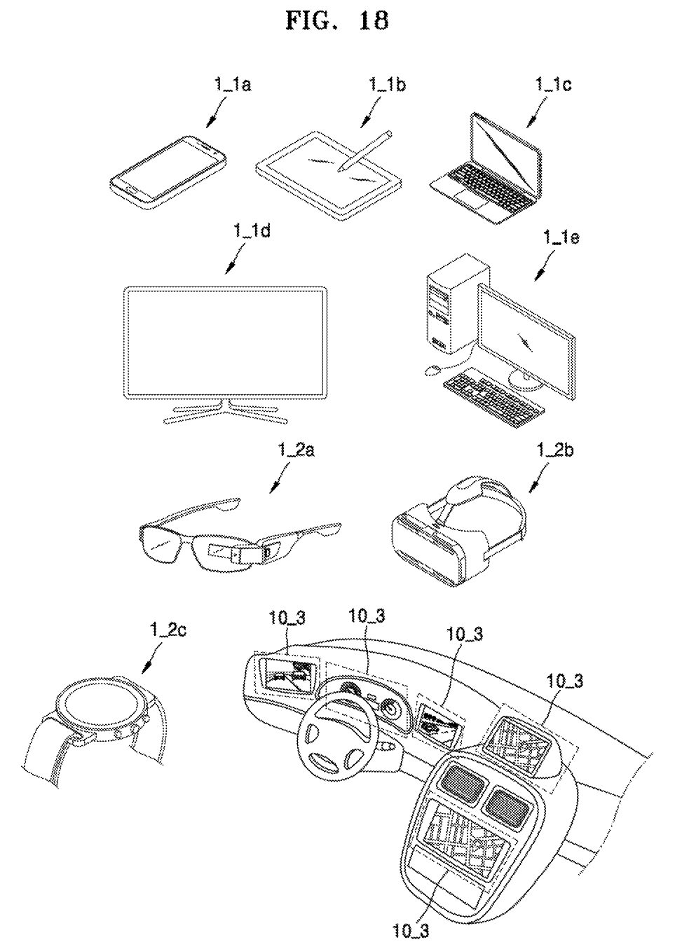

FIG. 18 is a schematic diagram of electronic apparatuses according to various embodiments.

Referring to FIG. 18, various electronic apparatuses including the display apparatus according to some embodiments may include not only an electronic apparatus for displaying images, such as a smart phone 1_1a, a tablet personal computer (PC) 1_1b, a laptop computer 1_1c, a television (TV) 1_1d, or a desk monitor 1_1e, but also a wearable electronic apparatus including a display module, such as smart glasses 1_2a, a head-mounted display 1_2b, or a smart watch 1_2c, and a vehicle electronic apparatus 10_3 including a display module, such as a center information display (CID) or a room mirror display arranged in the instrument panel, center fascia, or dashboard of a car.

According to some embodiments, a display apparatus, in which a viewing angle is restricted in one direction to relatively reduce reflection by a vehicle window, and a method of manufacturing the display apparatus may be implemented.

According to some embodiments, a manufacturing process for the display apparatus may be relatively simplified, and the durability and quality of the display apparatus may be relatively improved.

However, the scope of embodiments according to the present disclosure are not limited to these characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate;
a pixel layer over the substrate and comprising a pixel circuit and a display element; and
a shading unit over the pixel layer,
wherein the shading unit comprises:
a plurality of first shading walls extending in a first direction and spaced apart from each other in a second direction intersecting the first direction;
a plurality of second shading walls extending in the second direction and spaced apart from each other in the first direction; and
a plurality of third shading walls protruding from the plurality of first shading walls in the first direction and spaced apart from each other in the first direction and the second direction.

2. The display apparatus of claim 1, wherein a distance between two third shading walls adjacent to each other in the second direction is greater than a distance between two first shading walls adjacent to each other in the second direction.

3. The display apparatus of claim 1, wherein a distance between two first shading walls adjacent to each other in the second direction is equal to a length of each of the plurality of third shading walls in the second direction.

4. The display apparatus of claim 1, wherein the shading unit further comprises:
a plurality of first shading openings between the plurality of first shading walls and the plurality of third shading walls; and
a plurality of second shading openings between the plurality of first shading walls and the plurality of second shading walls.

5. The display apparatus of claim 4, wherein a length of each of the plurality of second shading openings in the first direction is greater than a length of each of the plurality of first shading openings in the first direction.

6. The display apparatus of claim 4, wherein the shading unit further comprises a transparent layer accommodated in the plurality of first shading openings and the plurality of second shading openings.

7. The display apparatus of claim 1, wherein a thickness of each of the plurality of second shading walls is greater than a thickness of each of the plurality of first shading walls.

8. The display apparatus of claim 1, wherein the plurality of first shading walls and the plurality of second shading walls intersect each other at a plurality of intersection portions.

9. An electronic apparatus comprising a display apparatus, wherein the display apparatus comprises:
a substrate;
a pixel layer over the substrate and comprising a pixel circuit and a display element; and
a shading unit over the pixel layer,
wherein the shading unit comprises:
a plurality of first shading walls extending in a first direction and spaced apart from each other in a second direction intersecting the first direction;
a plurality of second shading walls extending in the second direction and spaced apart from each other in the first direction; and
a plurality of third shading walls protruding from the plurality of first shading walls in the first direction and spaced apart from each other in the first direction and the second direction.

10. The electronic apparatus of claim 9, wherein a distance between two third shading walls adjacent to each other in the second direction is greater than a distance between two first shading walls adjacent to each other in the second direction, and
a distance between two second shading walls adjacent to each other in the second direction is equal to a length of each of the plurality of third shading walls in the second direction.

11. A method of manufacturing a display apparatus, the method comprising:
arranging a pixel layer over a substrate comprising a plurality of first areas, a plurality of second areas, and a plurality of third areas between the plurality of first areas and the plurality of second areas;
arranging a shading layer over the pixel layer to overlap the plurality of first areas, the plurality of second areas, and the plurality of third areas;
arranging a first layer over the shading layer to overlap the plurality of first areas, the plurality of second areas, and the plurality of third areas;
arranging a first organic layer comprising a first organic opening over the first layer to overlap the plurality of first areas and the plurality of third areas;
arranging a first inorganic layer over the first layer to overlap the plurality of first areas, the plurality of second areas, and the plurality of third areas;
arranging a second organic layer over the first inorganic layer to overlap the plurality of second areas and the plurality of third areas;
etching the first inorganic layer such that a first inorganic opening is formed in the first inorganic layer arranged in the plurality of first areas and the plurality of third areas;
removing the first organic layer and the second organic layer;
etching the first layer such that a first layer opening overlapping the first inorganic opening is formed in the first layer;
etching the shading layer such that a plurality of shading openings overlapping the first layer opening is formed in the shading layer; and
removing the first inorganic layer and the first layer.

12. The method of claim 11, wherein, in the arranging of the first inorganic layer, the first inorganic layer arranged in the plurality of first areas and the plurality of third areas covers the first organic layer.

13. The method of claim 11, wherein, in the arranging of the second organic layer, a height of the second organic layer in the plurality of third areas is less than or equal to a height of the first organic layer.

14. The method of claim 11, further comprising arranging a transparent layer in the plurality of shading openings.

15. The method of claim 14, wherein the plurality of shading openings comprise:
a plurality of first shading openings in the plurality of first areas; and
a plurality of second shading openings in each of the plurality of first areas and the plurality of third areas.

16. The method of claim 15, wherein a length of each of the plurality of second shading openings in a first direction is greater than a length of each of the plurality of first shading openings in the first direction.

17. The method of claim 11, wherein a shading wall is formed in the etching of the shading layer, and
the shading wall comprises:
a plurality of first shading walls extending in a first direction and spaced apart from each other in a second direction intersecting the first direction;
a plurality of second shading walls extending in the second direction and spaced apart from each other in the first direction; and
a plurality of third shading walls protruding from the plurality of first shading walls in the first direction and spaced apart from each other in the first direction and the second direction.

18. The method of claim 17, wherein a distance between two third shading walls adjacent to each other in the second direction is greater than a distance between two first shading walls adjacent to each other in the second direction.

19. The method of claim 17, wherein a distance between two second shading walls adjacent to each other in the second direction is equal to a length of each of the plurality of third shading walls in the second direction.

20. The method of claim 17, wherein a thickness of each of the plurality of second shading walls is greater than a thickness of each of the plurality of first shading walls.
